(19) United States
(12) Patent Application Publication
(10) Pub. No.: US 2009/0044064 A1
(43) Pub. Date: Feb. 12, 2009

(54) Scan path circuit and semiconductor integrated circuit

(75) Inventor: Naoto Sudo, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/222,288

(22) Filed: Aug. 6, 2008

(30) Foreign Application Priority Data
Aug. 8, 2007 (JP) 2007-206124

(51) Int. Cl. G01R 31/28

(52) U.S. Cl. 714/729; 714/E11.001

(57) ABSTRACT

Provided are a scan path circuit and a semiconductor integrated circuit that can reduce time necessary for shift operation. The scan path circuit includes: a first scan FF group (7) including serially connected three scan FFs (21) and connected to a test input terminal (3); a second scan FF group (8) including three scan FFs (21) that receive an output signal of the first scan FF group (7); a third scan FF group (9) including serially connected three scan FFs (21) and connected to a test output terminal (6); and a skip circuit (22) that inputs, in a shift operation mode of the scan FF (21), the output signal of the first scan FF group (7) to the second scan FF group (8) as well as to the third scan FF group (9).

### BACKGROUND OF THE INVENTION

1. Field of the Invention

The present invention relates to a scan path circuit and a semiconductor integrated circuit, in particular, a scan path circuit that adopts a scan path as a methodology for testing a circuit built in a semiconductor integrated circuit, and a semiconductor integrated circuit employing the scan path circuit.

2. Description of the Related Art

In recent years, circuit scale is increasing in semiconductor integrated circuits. As a circuit used for testing a circuit built in such a semiconductor integrated circuit, a scan path circuit is known that adopts a scan path. In the scan path circuit, in general, a scan chain is provided.

FIG. 14 shows an example of a conventional semiconductor integrated circuit. As shown in FIG. 14, the conventional semiconductor integrated circuit includes a target circuit 301, a scan chain 302, input terminals 303 (IN1, IN2, IN3, and IN4 of FIG. 14) of the target circuit 301, output terminals 304 (OUT1, OUT2, OUT3, and OUT4 of FIG. 14) of the target circuit 301, a test input terminal 305 (SIN of FIG. 14), a clock input terminal 306 (CLK of FIG. 14), a control signal input terminal 307 (SCAN_EN of FIG. 14), and a test output terminal 308 (SOT of FIG. 14).

A test signal is input through the test input terminal 305 to the scan chain 302. Further, an output signal of the scan chain 302 is output through the test output terminal 308.

The scan chain 302 has a plurality of flip-flops (each referred to as scan FF, hereinafter) 309 for inputting a test signal to the target circuit 301. Further, the plurality of scan FFs 309 are serially connected to each other.

The test input terminal 305 is connected to the scan FF 309 on one-end side of the scan chain 302. Further, the test output terminal 308 is connected to the scan FF 309 on the other-end side of the scan chain 302. Then, the plurality of scan FFs 309 serve as a shift register.

Then, each scan FF 309 shift-inputs a test signal input through the test input terminal 305. After that, each scan FF 309 inputs a test signal to the target circuit 301. Further, each scan FF 309 holds an output signal output from the target circuit 301. After that, each scan FF 309 shifts the held signal and then outputs the signal through the test output terminal 308. Further, each scan FF 309 is connected to the control signal input terminal 307 and the clock input terminal 306. Then, on the basis of a control signal input through the control signal input terminal 307 and a clock signal input through the clock input terminal 306, each scan FF 309 performs shift input of the test signal, input of the test signal into each circuit, hold of an output signal output from each circuit, and shift output of the output signal.

Nevertheless, when the size of the circuit built in the semiconductor integrated circuit increases, the number of scan FFs and the length of the scan chain increases accordingly. Further, when the size of the circuit built in the semiconductor integrated circuit increases, in general, the number of patterns of test signals also increases. Also, the necessary test time is proportional to the number of patterns of test signals and the length of the scan chain. Thus, a problem arises that, when a test is performed using a, scan chain, the necessary test time increases in accordance with an increase in size of the circuit built in the semiconductor integrated circuit. Here, since the major part of the necessary test time is the time necessary for shift, a technology is demanded for reducing the time necessary for shift.

Further, in recent years, design rule reduction is in progress in semiconductor integrated circuits. When a semiconductor integrated circuit fabricated with a deep submicron design rule is to be tested, defects cannot be removed by testing merely a single stuck at fault. Therefore, a delay fault and a bridge fault are needed to be tested. This causes an increase in number of patterns of test signals in accordance with the design rule reduction in semiconductor integrated circuits. Test signals are stored in a memory of a tester. Then, the amount of data of the test signals that occupy the memory of the tester increases in proportion to the number of patterns of test signals and the length of the scan chain. Thus, depending on the amount of the memory in the tester, the work of loading a pattern of test signals onto the memory of the tester is needed to be repeated more than once. This causes a problem of further increase in necessary test time.

Thus, there is known a technology that a plurality of scan chains are provided in each of which the number of scan FFs is reduced so that its length is reduced (e.g., Japanese Patent Application Laid-open No. 2004-226291). In Japanese Patent Application Laid-open No. 2004-226291, the reduction in number of scan FFs caused by reduction in number of scan FFs per chain is canceled out with an increase in number of scan chains. FIGS. 15 and 16 show a semiconductor integrated circuit disclosed in Japanese Patent Application Laid-open No. 2004-226291.

As shown in FIGS. 15 and 16, the semiconductor integrated circuit disclosed in Japanese Patent Application Laid-open No. 2004-226291 includes scan chains 401, 402, 403, and 404, a first test input terminal 405 (SIN1 of FIG. 15), a second test input terminal 406 (SIN2 of FIG. 15), an input selection circuit 407, a clock input terminal 408 (CLK of FIG. 15), a control signal input terminal 409 (SCAN_EN of FIG. 15), a first test output terminal 410 (SOT1 of FIG. 15), a second test output terminal 411 (SOT2 of FIG. 15), an output selection circuit 412, a command analyzing section 413, and a cycle determination section 414.

Further, each of the scan chains 401, 402, 403, and 404 has a plurality of scan FFs 415 for inputting a test signal to a plurality of circuits contained in the target circuit. The scans FFs 415 are serially connected to each of the scan chains 401, 402, 403, and 404.

FIG. 17 shows an example of a scan FF 415. As shown in FIG. 17, the scan FF 415 includes an SI terminal, an SO terminal, a D terminal, a Q terminal, a CL terminal, and an SMC terminal.

The SI terminal of the scan FF 415 located on the input side of each of the scan chains 401, 402, 403, and 404 is connected via the input selection circuit 407 to the first test input terminal 405 or the second test input terminal 406. Further, the SI terminal of each scan FF 415 other than the scan FF 415 located on the input side of each of the scan chains 401, 402, 403, and 404 is connected to the SO terminal of a scan FF 415 located adjacent on the input side. As such, the individual scan FFs 415 are serially connected to each other.

Further, the SO terminal of the scan FF 415 located on the output side of each of the scan chains 401, 402, 403, and 404 is connected via the output selection circuit 412 to the first test output terminal 410 or the second test output terminal 411.

Further, the D terminal and the Q terminal of each scan FF 415 in the scan chains 401, 402, 403, and 404 are connected to each circuit contained in the target circuit (not shown). Then, a test signal is input from the Q terminal of each scan FF 415 to each corresponding circuit, and then an output signal of each circuit is input to the D terminal of each scan FF 415.

The CL terminals of the scan chains 401, 402, 403, and 404 are connected to the clock input terminal 408. Further, the SMC terminals of the scan chains 401, 402, 403, and 404 are connected to the control signal input terminal 409. Then, on the basis of a control signal input through the control signal input terminal 409 and a clock signal input through the clock input terminal 408, each scan FF 415 performs shift input of the test signal, input of the test signal into each circuit, hold of an output signal output from each circuit, and shift output of the output signal.

The input selection circuit 407 is connected to the first test input terminal 405 and the second test input terminal 406.

Further, the output selection circuit 412 is connected to the first test output terminal 410 and the second test output terminal 411.

The command analyzing section 413 is connected to the first test input terminal 405 and the second test input terminal 406. Further, the command analyzing section 413 is connected to the clock input terminal 408, the input selection circuit 407, and the output selection circuit 412. Then, the command analyzing section 413 analyzes the test signals input through the first test input terminal 405 and the second test input terminal 406. Further, the command analyzing section 413 inputs to the input selection circuit 407 and the output selection circuit 412 an analysis result signal obtained by analyzing the test signals input through the first test input terminal 405 and the second test input terminal 406. Then, on the basis of the analysis result signal, the input selection circuit 407 selects any two of the scan chains 401, 402, 403, and 404 so as to connect the two to the first test input terminal 405 and the second test input terminal 406. Further, on the basis of the analysis result signal, the output selection circuit 412 selects any two of the scan chains 401, 402, 403, and 404 selected by the input selection circuit 407 so as to connect the two to the first test output terminal 410 and the second test output terminal 411.

The cycle determination section 414 is connected to the clock input terminal 408, the control signal input terminal 409, and the command analyzing section 413. Then, in a particular cycle having been set up in advance, the cycle determination section 414 inputs an analysis instruction signal to the command analyzing section 413. Then, when the analysis instruction signal is input, the command analyzing section 413 analyzes the test signals input through the first test input terminal 405 and the second test input terminal 406, and then outputs an analysis result signal to the input selection circuit 407 and the output selection circuit 412.

Next, the operation of the semiconductor integrated circuit disclosed in Japanese Patent Application Laid-open No. 2004-226291 is described below.

First, when a control signal “1” is input through the control signal input terminal 409, each scan FF 415 and the cycle determination section 414 are set into a shift mode.

Further, the command analyzing section 413 analyzes the test signals input through the first test input terminal 405 and the second test input terminal 406. For example, when the test signal input through the first test input terminal 405 is “01101100” while the test signal input through the second test input terminal 406 is “10001100”, the command analyzing section 413 analyzes the first signal in the test signal of the first test input terminal 405 and the first signal in the test signal of the second test input terminal 406, so as to obtain values of “0” and “1”, respectively. This analysis result signal is input to the input selection circuit 407 and the output selection circuit 412. Then, for example, as shown in FIG. 15, the first test input terminal 405 and the first test output terminal 410 are connected to the scan chain 401, while the second test input terminal 406 and the second test output terminal 411 are connected to the scan chain 404.

Then, a test signal is input from the first test input terminal 405 and the second test input terminal 406 to the scan chains 401 and 404, respectively. Then, on the basis of a clock signal input through the clock input terminal 408, each scan FF 415 in the scan chains 401 and 404 shift-inputs the test signal.

Further, in a particular cycle defined in advance, the cycle determination section 414 inputs an analysis instruction signal to the command analyzing section 413. Then, on the basis of the analysis result of the command analyzing section 413, the input selection circuit 407 switches the connection of the first test input terminal 405 to one of the scan chains 401 and 402. Further, on the basis of the analysis result, the input selection circuit 407 switches the connection of the second test input terminal 406 to one of the scan chains 403 and 404 (see FIGS. 15 and 16). Similarly, on the basis of the analysis result, the output selection circuit 412 switches the connection of the first test output terminal 410 to one of the scan chains 401 and 402. Further, on the basis of the analysis result, the output selection circuit 412 switches the connection of the second test output terminal 411 to one of the scan chains 403 and 404.

Then, when a control signal “0” is input through the control signal input terminal 409, each scan FF 415 is set into a capture mode. Then, each scan FF 415 outputs the test signal held in the shift mode through the Q terminal to the target circuit. Further, an output signal of the target circuit is input to each scan FF 415 via the D terminal. Thus, each scan FF 415 holds the corresponding output signal.

Then, when a control signal “1” is input through the control signal input terminal 409, each scan FF 415 is set into a shift mode. Then, each scan FF 415 shifts by outputting through the SO terminal the output signal held in the capture mode. As a result, the corresponding output signal is output through the first test output terminal 410 or the second test output terminal 411. Then, the corresponding output signal is compared with an expected value by the tester, so that pass or fail of each circuit contained in the target circuit is determined.

In Japanese Patent Application Laid-open No. 2004-226291 described above, the number of scan chains is increased so that the conventional case. Then, the scan chains that connect the first test input terminal 405 to the first test output terminal 410 and the second test input terminal 406 to the second test output terminal 411 are switched. By virtue of this, the necessary test time is reduced.

There is also known another technology that two scan chains are connected in parallel to each other to a test input terminal through which a test signal is input, and that an XOR operation is then performed on the output signals of the individual scan chains and then the result is output (e.g., Japanese Patent Application Laid-open No. 2003-194886).

Nevertheless, in Japanese Patent Application Laid-open No. 2004-226291, the number of patterns of test signals increases with increasing number of scan chains. This degrades the reduction effect for the necessary test time achieved by the reduction in length of the scan chain. Further, the number of scan chains that can be connected by a tester is limited depending on the tester. Thus, with the increasing number of scan chains, the range that can be tested in one test is limited to a narrower range. Thus, when the entire range is to be tested, the reduction effect for the necessary test time is degraded further. Further, with increasing size in semiconductor integrated circuits, the number of scan chains increases and hence the reduction effect for the necessary test time is degraded still further.

Further, in Japanese Patent Application Laid-open No. 2003-194886, the scan chain is divided into two. Nevertheless, this technology does not realize sufficient reduction in length of each scan chain. Thus, the necessary test time cannot satisfactorily be reduced.

### SUMMARY OF THE INVENTION

According to a first aspect of the present invention, there is provided a scan path circuit, including: a first scan FF group including serially connected K scan FFs (K is an integer satisfying K≧1) and connected to an input terminal; a second scan FF group including S scan FFs (S is an integer satisfying S≧1) serially connected to the first scan FF group; a third scan FF group including serially connected N scan FFs (N is an integer satisfying N≧1) and connected to an output terminal; and a skip circuit that inputs, in a shift operation mode of the scan FFs, an output signal of the first scan FF group to the third scan FF group.

According to the present invention, in the shift operation mode, a signal is shift-input from the first scan FF group to the second scan FF group, while the signal is similarly shift-input from the first scan FF group to the third scan FF group via the skip circuit. That is, the signal is shift-input to the second scan FF group and the third scan FF group at the same time. Thus, in the shift operation mode, the time necessary for shifting the signal to all the scan FFs can be reduced in comparison with the case of a scan chain where all the scan FFs are serially connected into a single chain.

According to the present invention, the time necessary for shift operation in the scan path circuit can be reduced.

### BRIEF DESCRIPTION OF THE DRAWINGS

In the accompanying drawings:

FIG. 1 is a circuit diagram showing a schematic configuration of a semiconductor integrated circuit according to the present invention;

FIG. 2A is a schematic diagram showing an example of a scan FF according to the present invention, while FIGS. 2B and 2C are schematic diagrams each showing an example of a control FF according to the present invention;

FIG. 3 is a circuit diagram showing a detailed configuration of a semiconductor integrated circuit according to Embodiment 1 of the present invention;

FIG. 4 is a flow chart showing a test method according to the present invention;

FIG. 5 is a flow chart for explaining a shift operation in a scan path circuit according to Embodiment 1 of the present invention;

FIG. 6 is a timing chart showing changes over time of signals on variable terminals, held signals in scan FFs, a held signal in a control FF, and an output signal from a selector in the semiconductor integrated circuit according to Embodiment 1 of the present invention;

FIG. 7 is a circuit diagram showing a detailed configuration of a semiconductor integrated circuit according to Embodiment 2 of the present invention;

FIG. 8 is a flow chart for explaining a shift operation in a scan path circuit according to Embodiment 2 of the present invention;

FIG. 9 is a timing chart showing changes over time of signals on variable terminals, held signals in scan FFs, a held signal in a control FF, and an output signal from a selector in the semiconductor integrated circuit according to Embodiment 2 of the present invention;

FIG. 10 is a circuit diagram showing a detailed configuration of a semiconductor integrated circuit according to Modification 1 of Embodiment 2 of the present invention;

FIG. 11 is a circuit diagram showing a detailed configuration of a semiconductor integrated circuit according to Embodiment 3 of the present invention;

FIG. 12 is a flow chart for explaining a shift operation in a scan path circuit according to Embodiment 3 of the present invention;

FIG. 13 is a timing chart showing changes over time of signals on variable terminals, held signals in scan FFs, a held signal in a control FF, and an output signal from a selector in the semiconductor integrated circuit according to Embodiment 3 of the present invention;

FIG. 14 is a circuit diagram showing a detailed configuration of a conventional scan chain and a conventional semiconductor integrated circuit;

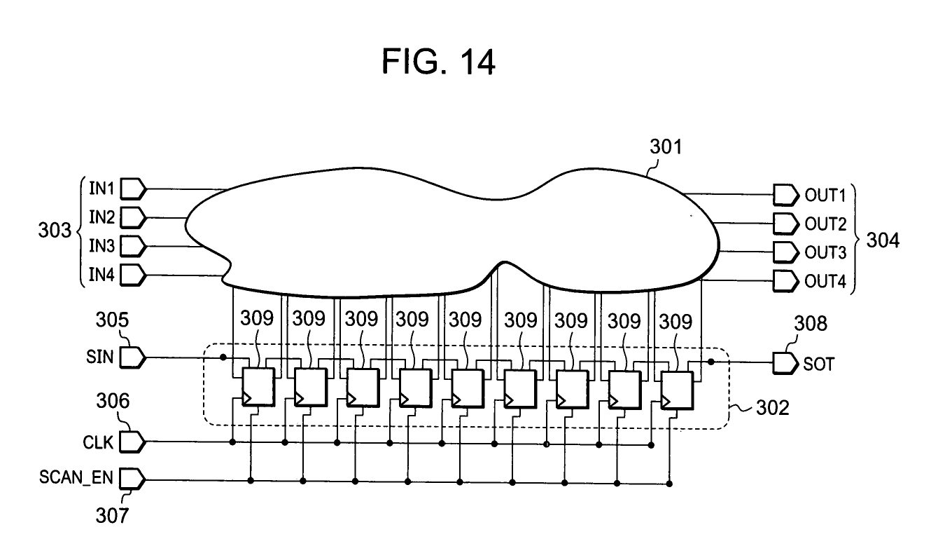

FIG. 15 is a circuit diagram showing a detailed configuration of a conventional scan chain and a conventional semiconductor integrated circuit;

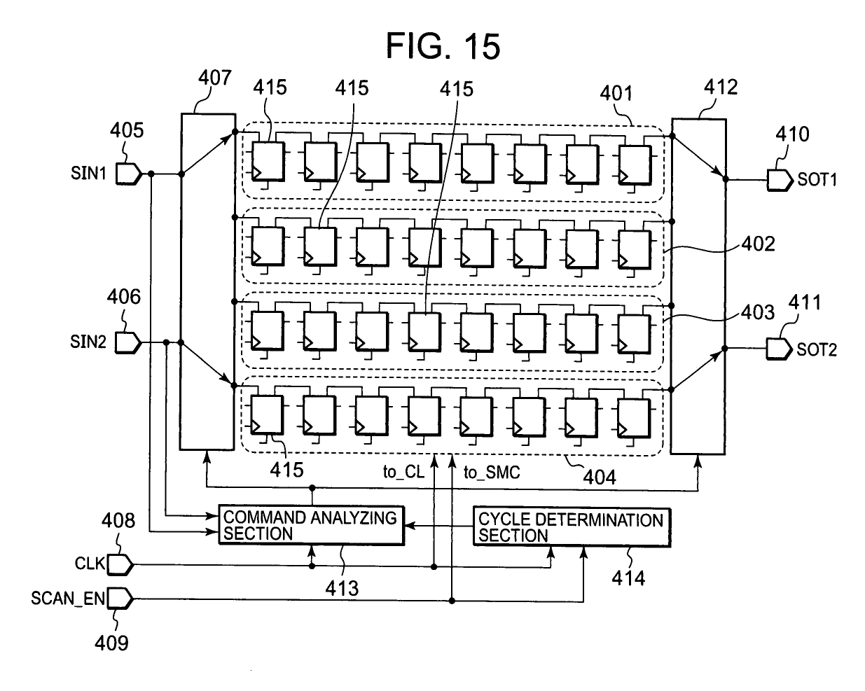

FIG. 16 is a circuit diagram showing a detailed configuration of the conventional scan chain and the conventional semiconductor integrated circuit; and

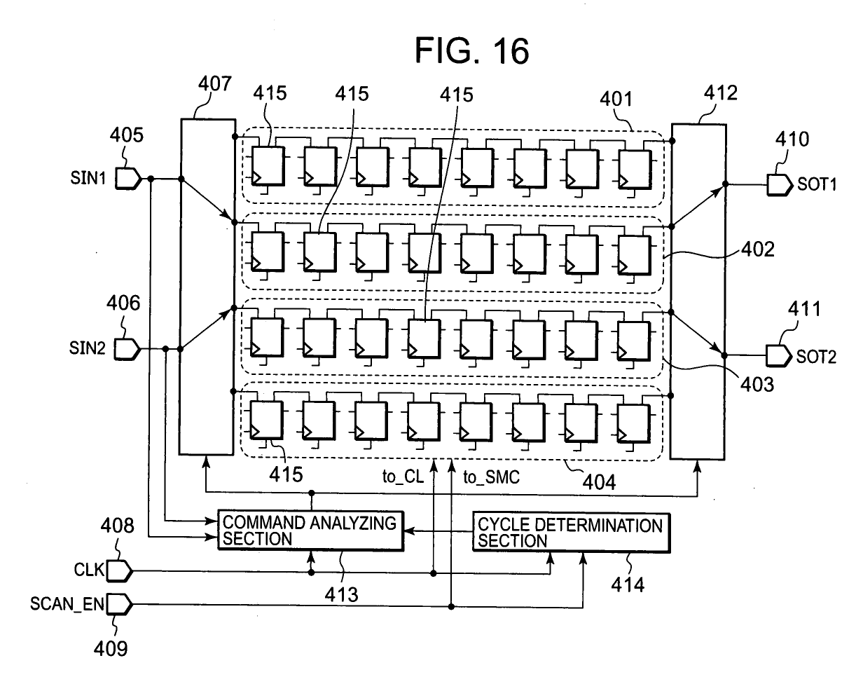

FIG. 17 is a schematic diagram showing a scan FF provided in the conventional scan chain.

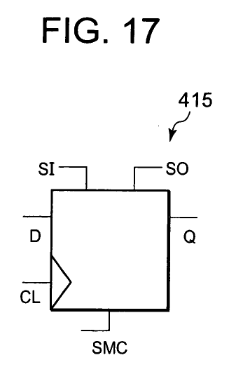

### DETAILED DESCRIPTION OF THE PREFERRED EMBODIMENTS

Embodiments where the present invention can be applied are described below. Here, the present invention is not limited to the following embodiments.

### Embodiment 1

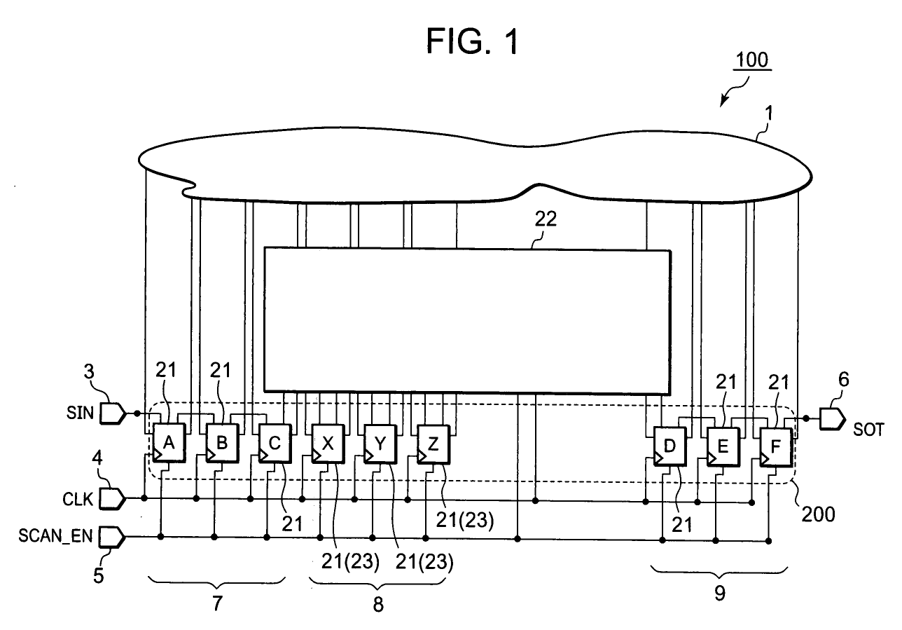

A scan path circuit 200 and a semiconductor integrated circuit 100 employing this scan path circuit 200 according to Embodiment 1 of the present invention are described below with reference to FIGS. 1 to 4. FIG. 1 is a circuit diagram showing a schematic configuration of the semiconductor integrated circuit 100 according to the present invention.

As shown in FIG. 1, the semiconductor integrated circuit 100 includes a target circuit 1, the scan path circuit 200, a test input terminal 3 (input terminal; SIN of FIG. 1), a clock input terminal 4 (CLK of FIG. 1), a control signal input terminal 5 (SCAN_EN of FIG. 1), a test output terminal 6 (output terminal; SOT of FIG. 1), and the like.

Here, the target circuit 1 has an ordinary input terminal (not shown) through which a signal is input to the target circuit 1, and an ordinary output terminal (not shown) through which a signal of the target circuit 1 is output.

A test signal is input through the test input terminal 3 to the scan path circuit 200. Further, an output signal output from the scan path circuit 200 is output through the test output terminal 6.

As shown in FIG. 1, the scan path circuit 200 has a plurality of scan flip-flops (each referred to as scan FF, hereinafter) 21 and a skip circuit 22.

The skip circuit 22 is connected between one scan FF 21 and another scan FF 21. Further, the individual scan FFs 21 located on the former stage side relative to the skip circuit 22 are serially connected to each other. Further, the individual scan FFs 21 located on the latter stage side relative to the skip circuit 22 are serially connected to each other. Further, the scan FF 21 of the first stage is connected to the test input terminal 3, while the scan FF 21 of the last stage is connected to the test output terminal 6.

Further, the scan path circuit 200 has a plurality of skip scan FFs 23 that are connected to the skip circuit 22 and receive an output signal of the scan FF 21 of the preceding stage of the skip circuit 22. Then, a test signal input through the test input terminal 3 is shift-input in the individual scan FFs 21 located on the former stage side relative to the skip circuit 22. Then, the test signal is input from the scan FF 21 of the last stage on the former stage side relative to the skip circuit 22 via the skip circuit 22 to the scan FF 21 of the first stage on the latter stage side relative to the skip circuit 22. At the same time, the test signal is input from the scan FF 21 of the last stage on the former stage side relative to the skip circuit 22 via the skip circuit 22 to the individual skip scan FFs 23. Further, the test signal is shift-input in the individual scan FFs 21 located on the latter stage side relative to the skip circuit 22.

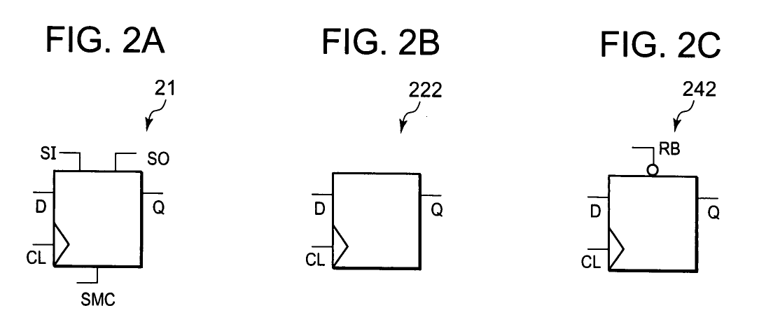

Further, FIG. 2A shows an example of a flip-flop used as the scan FF 21 and the skip scan FF 23.

As shown in FIG. 2A, the scan FF 21 and the skip scan FF 23 include an SI terminal, an SO terminal, a D terminal, a Q terminal, a CL terminal, an SMC terminal, and the like. Then, the SI terminal of the scan FF 21 provided in the first stage is connected to the test input terminal 3. Further, the SO terminal of the scan FF 21 provided in the last stage is connected to the test output terminal 6. Further, in a case of serially connected scan FFs 21, the SO terminal of the scan FF 21 of a preceding stage is connected to the SI terminal of the scan FF 21 of the subsequent stage. Then, in each scan FF 21 and each skip scan FF 23, the test signal input through the test input terminal 3 is input through the SI terminal and then output through the SO terminal. As a result, the test signal is shift-input to the individual scan FFs 21 and the individual skip scan FFs 23.

Further, the D terminals and the Q terminals of the individual scan FFs 21 and the individual skip scan FFs 23 are connected to the target circuit 1. Then, the test signals from the Q terminals of the individual scan FFs 21 and the individual skip scan FFs 23 are input to the target circuit 1. Further, the result signals output from the target circuit 1 are input to the D terminals of the individual scan FFs 21 and the individual skip scan FFs 23.

Further, the SMC terminals of the individual scan FFs 21 and the individual skip scan FFs 23 are connected to the control signal input terminal 5. Then, when a control signal (e.g., a signal “1”) that instructs a shift operation mode is input through the control signal input terminal 5, the individual scan FFs 21 and the individual skip scan FFs 23 shift the test signal or the result signal. Further, when a control signal (e.g., a signal “0”) that instructs a capture operation mode (normal operation mode) is input through the control signal input terminal 5, the individual scan FFs 21 and the individual skip scan FFs 23 input test signals through the Q terminals to the target circuit 1, and then hold result signals output from the target circuit 1.

Further, the CL terminals of the individual scan FFs 21 and the individual skip scan FFs 23 are connected to the clock input terminal 4. Then, in synchronization with a clock signal input through the clock input terminal 4, the individual scan FFs 21 and the individual skip scan FFs 23 perform the processings of shift input, input of the test signal to the target circuit 1, and hold of the output signal output from the target circuit 1.

Thus, the individual scan FFs 21 and the individual skip scan FFs 23 serve as a shift register. In the following description, when the individual scan FFs 21 and the individual skip scan FFs 23 need not be discriminated in particular, they are simply referred to as the scan FFs 21. Here, it is sufficient that each scan FF 21 is a circuit having a function of holding a logical value. However, in place of the scan FF 21, for example, a random access memory (RAM) may be employed.

Here, a plurality of scan FFs 21 provided on the former stage side relative to the skip circuit 22 are grouped into a first scan FF group 7, while a plurality of skip scan FFs 23 connected to the skip circuit 22 are grouped into a second scan FF group 8, and while a plurality of scan FFs 21 provided on the latter stage side relative to the skip circuit 22 are grouped into a third scan FF group 9.

That is, as shown in FIG. 1, the scan path circuit 200 includes the first scan FF group 7, the second scan FF group 8, the third scan FF group 9, and the skip circuit 22.

The first scan FF group 7 includes the serially connected K scan FFs 21 (K is an integer satisfying K≧1) and is connected to the test input terminal 3.

The second scan FF group 8 includes S scan FFs (S is an integer satisfying S≧1) 21 that receive an output signal of the first scan FF group 7.

The third scan FF group 9 includes the serially connected N scan FFs 21 (N is an integer satisfying N≧1) and is connected to the test output terminal 6.

For simplicity of the description, this embodiment is described below for an exemplary case of K=3, S=3, and N=3. That is, as shown in FIG. 1, the first scan FF group 7 includes a scan FF_A 21, a scan FF_B 21, and a scan FF_C 21. Further, the second scan FF group 8 includes a scan FF_X 21, a scan FF_Y 21, and a scan FF_Z 21. Further, the third scan FF group 9 includes a scan FF_D 21, a scan FF_E 21, and a scan FF_F 21. In the following description, when the scan FFs _A, _B, _C, _D, _E, _F, _X, _Y, and _Z 21 need not be discriminated in particular, they are simply referred to as the scan FFs 21.

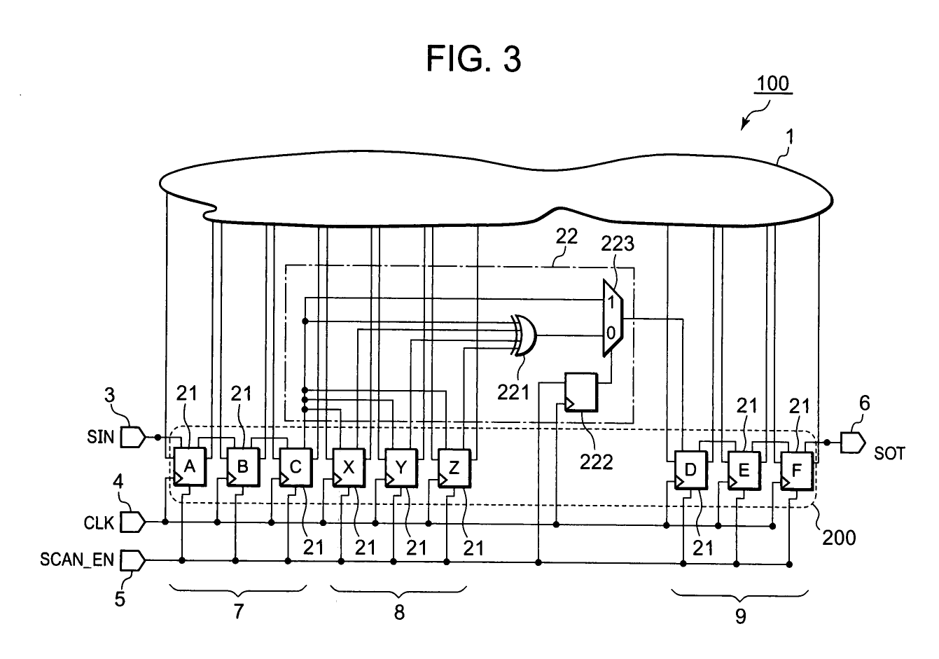

FIG. 3 shows a detailed configuration of the semiconductor integrated circuit 100.

As shown in FIG. 3, the skip circuit 22 includes an XOR circuit 221 (logic circuit), a control flip-flop (referred to as control FF, hereinafter) 222, a selector 223, and the like.

Further, the skip circuit 22 connects the SO terminal of the scan FF_C 21 of the last stage in the first scan FF group 7 to the SI terminals of the scan FF_X 21, the scan FF_Y 21, and the scan FF_Z 21 of the second scan FF group 8.

The XOR circuit 221 calculates the exclusive logical sum over the output signals of the scan FF_C 21, the scan FF_X 21, the scan FF_Y 21, and the scan FF_Z 21.

FIG. 2B shows an example of a flip-flop used as the control FF 222. As shown in FIG. 2B, the control FF 222 has a D terminal, a Q terminal, and a CL terminal.

The D terminal is connected to the control signal input terminal 5. Further, the Q terminal is connected to a control point (described later) of the selector 223. Further, the CL terminal is connected to the clock input terminal 4. Then, at the time of a rise of the clock signal input through the clock input terminal 4, the control FF 222 holds the control signal input through the control signal input terminal 5. Further, at the time of the rise of the clock signal input through the clock input terminal 4, the control FF 222 inputs the held control signal through the Q terminal to the control point of the selector 223.

The selector 223 has a first input point, a second input point, the control point, and an output point.

The first input point (“1” of FIG. 3) is connected to the SO terminal of the scan FF_C 21 of the last stage in the first scan FF group 7. The second input point (“0” of FIG. 3) is connected to the XOR circuit 221. Further, the output point is connected to the SI terminal of the scan FF_D 21 of the first stage in the third scan FF group 9.

Then, on the basis of the control signal input through the control point, the selector 223 selects any one of the signal input through the first input point and the signal input through the second input point so as to input the signal to the scan FF_D 21.

Specifically, when a control signal “1” is input through the control point, the selector 223 selects the signal input through the first input point so as to input the signal to the scan FF_D 21. That is, when the control signal “1” is input, the selector 223 selects the output signal of the scan FF_C 21 so as to input the signal to the scan FF_D 21.

Further, when a control signal “0” is input through the control point, the selector 223 selects the signal input through the second input point so as to input the signal to the scan FF_D 21. That is, when the control signal “0” is input, the selector 223 selects the output signal of the XOR circuit 221 so as to input the signal to the scan FF_D 21.

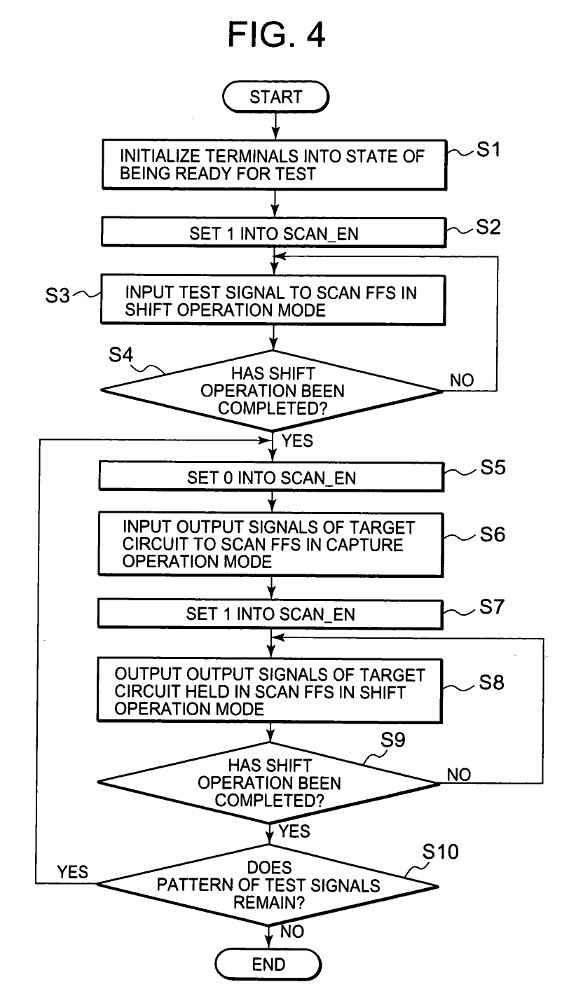

Next, a test method employing the scan path circuit 200 according to the present invention is described below with reference to a flow chart shown in FIG. 4.

First, the control signal input terminal 5, the clock input terminal 4, the test input terminal 3, the test output terminal 6, and the like are initialized into a state that a test is ready (Step S1). Specifically, corresponding terminals of a tester are connected to the individual terminals, while signals to be input to the individual terminals are set up.

Then, when a control signal “1” that instructs a shift operation mode is input through the control signal input terminal 5 (Step S2), in synchronization with a rise of the clock signal input through the clock input terminal 4, the control signal “1” is input to the SMC terminal of each scan FF 21. Accordingly, each scan FF 21 is set into a shift operation mode. Then, each scan FF 21 holds the test signal input through the test input terminal 3 or from a scan FF 21 of the preceding stage. At the same time, each scan FF 21 inputs the held test signal to the scan FF 21 of the subsequent stage (Step S3).

Then, it is determined whether the shift operation has been completed, that is, whether the test signal has been input to each scan FF 21 (Step S4). This determination may be performed automatically, for example, on the basis of whether the tester has output a clock signal necessary for inputting the test signal to each scan FF 21, or may alternatively be performed by an operator who carries out the test, on the basis of a signal output through the test output terminal 6 of the scan path circuit 200. Further, the determination may be performed by another method.

In Step S4, when it is determined that the shift operation has not been completed yet (Step S4; No), the procedure returns to the processing in Step S3.

In Step S4, when it is determined that the shift operation has been completed (Step S4; Yes), a control signal “0” that instructs a capture operation mode is input to the control signal input terminal 5 (Step S5). Then, in synchronization with a rise of the clock signal input through the clock input terminal 4, the control signal “0” is input to the SMC terminal of each scan FF 21 so that each scan FF 21 is set into a capture mode. Then, each scan FF 21 outputs a test signal to the target circuit 1, and then holds a result signal output from the target circuit 1 (Step S6).

Then, when a control signal “1” that instructs a shift operation mode is input through the control signal input terminal 5 (Step S7), in synchronization with a rise of the clock signal input through the clock input terminal 4, the control signal “1” is input to the SMC terminal of each scan FF 21. Accordingly, each scan FF 21 is set into a shift operation mode. Then, each scan FF 21 inputs the held result signal to the scan FF 21 of the subsequent stage. At the same time, each scan FF 21 holds the test signal input through the test input terminal 3 or from a scan FF 21 of the preceding stage (Step S8).

Then, it is determined whether the shift operation has been completed, that is, whether the result of each scan FF 21 has been output (Step S9). This determination may be performed automatically, for example, on the basis of whether the tester has output a clock signal necessary for outputting the result signal of each scan FF 21, or may alternatively be performed by the operator who carries out the test, on the basis of a signal output through the test output terminal 6 of the scan path circuit 200. Further, the determination may be performed by another method.

In Step S9, when it is determined that the shift operation has not been completed yet (Step S9; No), the procedure returns to the processing in Step S8.

In Step S9, when it is determined that the shift operation has been completed (Step S9; Yes), it is determined whether a pattern of test signals not yet tested remains (Step S10). This determination may be performed automatically, for example, on the basis of whether the tester has output clock signals necessary for the test to be carried out, for all the patterns of test signals, or may alternatively be performed by an operator who carries out the test, on the basis of a signal output through the test output terminal 6 of the scan path circuit 200. Further, the determination may be performed by another method.

In Step S10, when it is determined that a pattern of test signals not yet tested remains (Step S10; No), the procedure returns to Step S5.

In Step S10, when it is determined that a pattern of test signals not yet tested does not remain, the present processing is terminated.

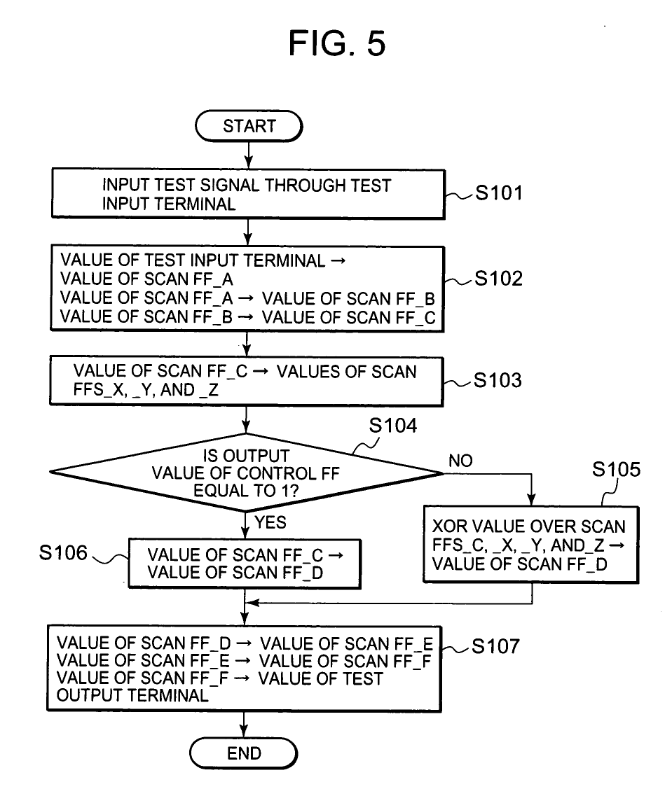

Next, the shift operation in the scan path circuit 200 according to Embodiment 1 of the present invention is described below with reference to a flow chart shown in FIG. 5.

First, when a test signal is input through the test input terminal 3 (Step S101), in synchronization with the first rise of the clock signal input through the clock input terminal 4, the test signal at the first bit is held in the scan FF_A 21. Further, in synchronization with the second rise of the clock signal, the test signal at the first bit that is held in the scan FF_A 21 is held in the scan FF_B 21. At the same time, the scan FF_A 21 holds the test signal at the second bit input through the test input terminal 3. Further, in synchronization with the third rise of the clock signal, the test signal at the first bit that is held in the scan FF_B 21 is held in the scan FF_C 21. At the same time, the scan FF_B 21 holds the test signal at the second bit that is held by the scan FF_A 21. Further, at the same time, the scan FF_A 21 holds the test signal at the third bit input through the test input terminal 3 (Step S102).

Then, in synchronization with the fourth rise of the clock signal input through the clock input terminal 4, the test signal at the first bit that is held in the scan FF_C 21 is held in the scan FF_X 21, the scan FF_Y 21, and the scan FF_Z 21 (Step S103).

Further, at that time, the selector 223 determines whether the signal input through the control point from the control FF 222 is “1” (Step S104).

In Step S104, when the selector 223 determines that the signal input through the control point is “0” (Step S104; No), the selector 223 selects the signal input through the second input point so as to input the signal to the scan FF_D 21. In other words, the selector 223 selects the signal output from the XOR circuit 221 so as to input the signal to the scan FF_D 21. That is, the selector 223 inputs to the scan FF_D 21 a signal obtained as the exclusive logical sum over the output signals of the scan FF_C 21, the scan FF_X 21, the scan FF_Y 21, and the scan FF_Z 21.

Further, the scan FF_D 21 holds the signal input from the selector 223 (Step S105).

In Step S104, when the selector 223 determines that the signal input through the control point is “1” (Step S104; Yes), the selector 223 selects the signal input through the first input point so as to input the signal to the scan FF_D 21. In other words, the selector 223 selects the signal output from the scan FF_C 21 so as to input the signal to the scan FF_D 21. That is, the selector 223 inputs the test signal at the first bit to the scan FF_D 21.

Further, the scan FF_D 21 holds the signal input from the selector 223 (Step S106).

Then, in synchronization with the fifth rise of the clock signal input through the clock input terminal 4, the signal that is held in the scan FF_D 21 is held in the scan FF_E 21. Specifically, the scan FF_E 21 holds a signal obtained as the exclusive logical sum over the output signals of the scan FF_C 21, the scan FF_X 21, the scan FF_Y 21, and the scan FF_Z 21, or alternatively the test signal at the first bit. Further, in synchronization with the sixth rise of the clock signal, the signal that is held in the scan FF_E 21 is held in the scan FF_F 21. Further, in synchronization with the seventh rise of the clock signal, the signal that is held in the scan FF_F 21 is output through the test output terminal 6 (Step S107).

That is, in the scan path circuit 200 according to this embodiment, shift input of a signal into the nine scan FFs 21 takes the time of six clocks.

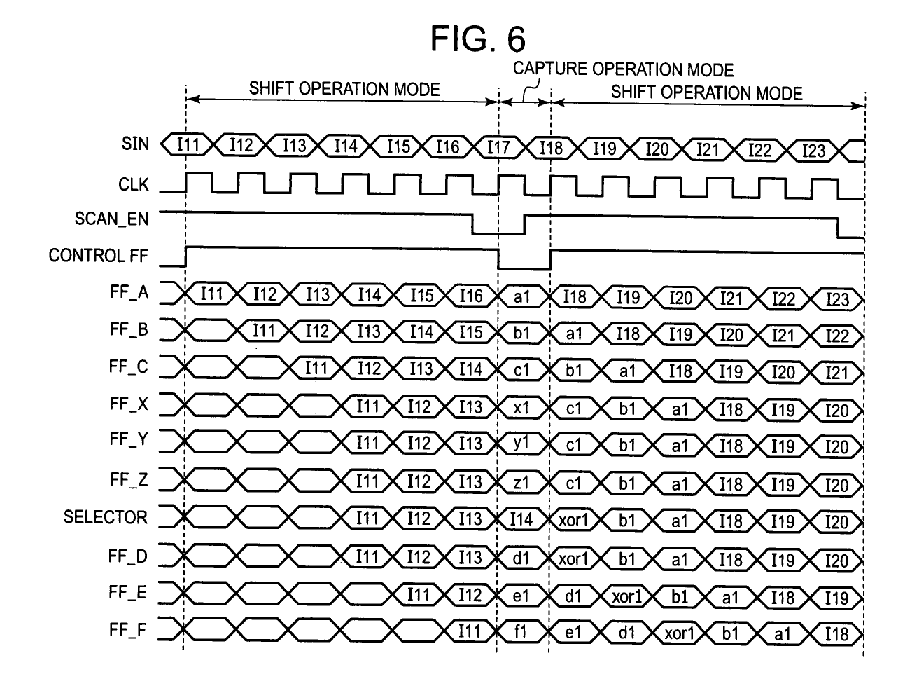

Next, changes over time in the output signals of the individual terminals, the held signals in the individual scan FFs 21, the held signal in the control FF 222, and the output signal of the selector 223 in the scan path circuit 200 according to Embodiment 1 of the present invention are described below with reference to a timing chart shown in FIG. 6.

Here, in an initial state, it is assumed that each scan FF 21 holds an indeterminate value and that the control FF 222 holds “0”.

First, a control signal “1” that instructs a shift operation mode is input through the control signal input terminal 5, while a test signal “I11” is input through the test input terminal 3. Then, in synchronization with the first rise of the clock signal, the scan FF 21 is set into a shift operation mode. Accordingly, the scan FF_A 21 holds the test signal “I11”. Further, each of the scan FFs _B, _C, _X, _Y, _Z, _E, and _F 21 holds the signal of a scan FF 21 of the preceding stage. Further, as shown in FIG. 6, in synchronization with the first rise of the clock signal input through the clock input terminal 4, the control FF 222 holds the signal “1”. At the same time, the control FF 222 inputs a signal “0” to the control point of the selector 223. Accordingly, the selector 222 selects the output signal of the XOR circuit 221 so as to input the signal to the scan FF_D 21. Thus, the scan FF_D 21 holds the output signal of the XOR circuit 221. That is, the scan FFs _B to _F and _X to _Z hold an indeterminate value.

Then, in synchronization with the second rise of the clock signal, the scan FF_A 21 holds the test signal “I12” input through the test input terminal 3. At the same time, the scan FF_A 21 inputs the test signal “I11” to the scan FF_B 21. Further, the scan FF_B 21 holds the test signal “I11” input from the scan FF_A 21. Further, in synchronization with the second rise of the clock signal, the control FF 222 inputs the signal “1” to the control point of the selector 223. Thus, the selector 223 inputs the output signal of the scan FF_C 21 to the scan FF_D 21. Accordingly, the scan FF_D 21 holds the output signal of the scan FF_C 21. Each of the other scan FFs 21 holds the signal of a scan FF 21 of the preceding stage. That is, the scan FFs _C to _F and _X to _Z 21 hold an indeterminate value.

Similarly, in synchronization with the third rise of the clock signal, the scan FF_A 21 holds the test signal “I13”, the scan FF_B 21 holds the test signal “I12”, and the scan FF_C 21 holds the test signal “I11”. The other scan FFs 21 hold an indeterminate value.

Then, in synchronization with the fourth rise of the clock signal, the scan FF_A 21 holds the test signal “I14”, the scan FF_B 21 holds the test signal “I13”, and the scan FF_C 21 holds the test signal “I12”.

Further, at the same time, the scan FFs _X, _Y, and _Z 21 hold the test signal “I11” that is held in the scan FF_C 21.

Further, at the same time,the scan FF_D 21 holds the output signal of the selector 223. At that time, the control FF 222 inputs a control signal “1”. Thus, the selector 223 selects the signal input through the first input point so as to input the signal to the scan FF_D 21. Accordingly, the scan FF_D 21 holds the test signal “I11” that is held in the scan FF_C 21. That is, the scan FFs _X, _Y, _Z, and _D hold the same signal.

The other scan FFs 21 hold an indeterminate value.

Similarly, in synchronization with the fifth rise of the clock signal, the scan FFs _A, _B, _C, _X, _Y, _Z, and _D 21 hold “I15”, “I14”, “I13”, “I12”, “I12”, “I12”, and “I12”, respectively. Further, the scan FF_E 21 holds the test signal “I11” that is held in the scan FF_D 21. Further, the scan FF_F 21 holds an indeterminate value.

Similarly, in synchronization with the sixth rise of the clock signal, the scan FFs _A, _B, _C, _X, _Y, _Z, _D, _E, and _F 21 hold “I16”, “I15”, “I14”, “I13”, “I13”, “I13”, “I13”, “I12”, and “I11”, respectively.

Then, at the sixth fall of the clock signal, a control signal “0” that instructs a capture operation mode is input through the control signal input terminal 5. Then, as shown in FIG. 6, in synchronization with the seventh rise of the clock signal input through the clock input terminal 4, the control FF 222 holds the signal “0”. Further, in synchronization with the first rise of the clock signal, the scan FF 21 is set into a capture operation mode. Thus, each scan FF 21 inputs the held test signal to the target circuit 1. Further, each scan FF 21 holds a result signal output from the target circuit 1. Specifically, the scan FFs _A, _B, _C, _X, _Y, _Z, _D, _E, and _F 21 hold the result signals “a1”, “b1”, “c1”, “x1”, “y1”, “z1”, “d1”, “e1”, and “f1”, respectively.

Then, at the seventh fall of the clock signal, a control signal “1” that instructs a shift operation mode is input through the control signal input terminal 5. Then, in synchronization with the eighth rise of the clock signal, the scan FF 21 is set into a shift operation mode. Accordingly, the scan FF_A 21 holds the test signal “I18”. Each of the scan FFs _B, _C, _X, _Y, _Z, _E, and _F 21 holds the signal of a scan FF 21 of the preceding stage. That is, the scan FFs _B, _C, _X, _Y, _Z, _E, and _F 21 hold the result signals “a1”, “b1”, “c1”, “c1”, “c1”, “d1”, and “e1”, respectively.

Further, as shown in FIG. 6, in synchronization with the eighth rise of the clock signal input through the clock input terminal 4, the control FF 222 holds the signal “1”. At the same time, the control FF 222 inputs a signal “0” to the control point of the selector 223. Thus, the selector 223 selects the signal input through the second input point so as to input the signal to the scan FF_D 21. That is, the selector 223 selects the output signal of the XOR circuit 221 so as to input the signal to the scan FF_D 21. Thus, the scan FF_D 21 holds the signal of exclusive logical sum among the signals of the scan FFs _C, _X, _Y, and _Z 21. Specifically, the scan FF_D 21 holds the signal of exclusive logical sum “xor1” among “c1”, “x1”, “y1”, and “z1”.

Further, a signal “f1” is output through the test output terminal 6.

Then, in synchronization with the ninth rise of the clock signal, the scan FF_A 21 holds the test signal “I19”, and at the same time, inputs a test signal “I18” to the scan FF_B 21. The scan FFs _B, _C, _X, _Y, _Z, _E, and _F 21 hold the signals “I18”, “a1”, “b1”, “b1”, “b1”, “xor1”, and “d1”, respectively.

Further, the control FF 222 inputs the signal “1” to the control point of the selector 223. Thus, the selector 223 selects the signal input through the first input point so as to input the signal to the scan FF_D 21. That is, the selector 223 selects the output signal of the scan FF_C 21 so as to input the signal to the scan FF_D 21. Thus, the scan FF_D 21 holds the signal “b1”.

Further, a signal “e1” is output through the test output terminal 6.

Similarly, in synchronization with a rise of the clock signal, the scan FF_A 21 holds the test signal input through the test input terminal 3. Each of the scan FFs _B, _C, _X, _Y, _Z, _E, and _F 21 holds the signal of a scan FF 21 of the preceding stage. Further, the scan FF_D 21 holds the output signal of the scan FF_C 21. Then, in synchronization with a rise of the clock signal, result signals “d1”, “xor1”, “b1”, and “a1” are sequentially output through the test output terminal 6. Further, at the same time, the scan FFs _A, _B, _C, _X, _Y, _Z, _D, _E, and _F 21 hold the test signals “I23”, “I22”, “I21”, “I20”, “I20”, “I20”, “I20”, “I19”, and “I18”, respectively.

That is, during the time (first time period) of one clock after the scan FF 21 has transited from a capture operation mode to a shift operation mode, the selector 223 selects the output signal of the XOR circuit 221 so as to input the signal to the scan FF_D 21. Further, in the time (second time period) other than the above-mentioned time of one clock in the shift operation mode, the selector 223 selects the output signal of the scan FF_C 21 so as to input the signal to the scan FF_D 21. Thus, result signals “f1”, “e1”, “d1”, “xor1”, “b1”, and “a1” are output through the test output terminal 6. Here, “xor1” is the exclusive logical sum among “c1”, “x1”, “y1”, and “z1”. Accordingly, a signal in which the result signals held in the scan FFs _C, _X, _Y, and _Z 21 are reflected is output through the test output terminal 6.

As described above, according to the scan path circuit 200 and the semiconductor integrated circuit 100 according to Embodiment 1 of the present invention, the configuration includes: the first scan FF group 7 including serially connected three scan FFs 21 and connected to the test input terminal 3; the second scan FF group 8 including three scan FFs 21 serially connected to the first scan FF group 7; the third scan FF group 9 including serially connected three scan FFs 21 and connected to the test output terminal 6; and a skip circuit 22 for inputting an output signal of the first scan FF group 7 to the third scan FF group 9 in a shift operation mode of the scan FFs 21.

As a result, in a shift operation mode, a signal is shift-input from the first scan FF group 7 to the second scan FF group 8, while the signal is similarly shift-input from the first scan FF group 7 to the third scan FF group 9 via the skip circuit 22. That is, the signal is shift-input to the second scan FF group 8 and the third scan FF group 9 at the same time. Thus, in a shift operation mode, the time necessary for shifting the signal to all the scan FFs 21 is reduced in comparison with the case of a scan chain where all the scan FFs 21 are serially connected into a single chain. In the example described in this embodiment, the signal is shift-input to the nine scan FFs 21 in the time of six clocks. Thus, the achieved reduction is the time of three clocks.

Further, in a capture operation mode, each scan FF 21 inputs the test signal to the target circuit 1, and at the same time holds a result signal output from the target circuit 1. During the time of one clock after transition from a capture operation mode to a shift operation mode, the selector 223 of the skip circuit 22 inputs to the scan FF_D 21 of the third scan FF group 9 a signal obtained as the exclusive logical sum over the output signal of the scan FF_C 21 of the first scan FF group 7 and the output signals of the scan FFs _X, _Y, and _Z of the second scan FF group 8. Moreover, during the time other than the above-mentioned time of one clock in the shift operation mode, the selector 223 inputs the output signal of the scan FF_C 21 of the first scan FF group 7 to the scan FF_D 21 of the third scan FF group 9.

As a result, the result signals of the scan FFs _A, _B, and _D to _F 21 are output through the test output terminal 6, while the signal obtained as the exclusive logical sum over the result signals of the scan FFs _C, _X, _Y, and _Z is output. Thus, when the signal output through the test output terminal 6 is compared with an expected signal, the target circuit 1 can be tested.

### Embodiment 2

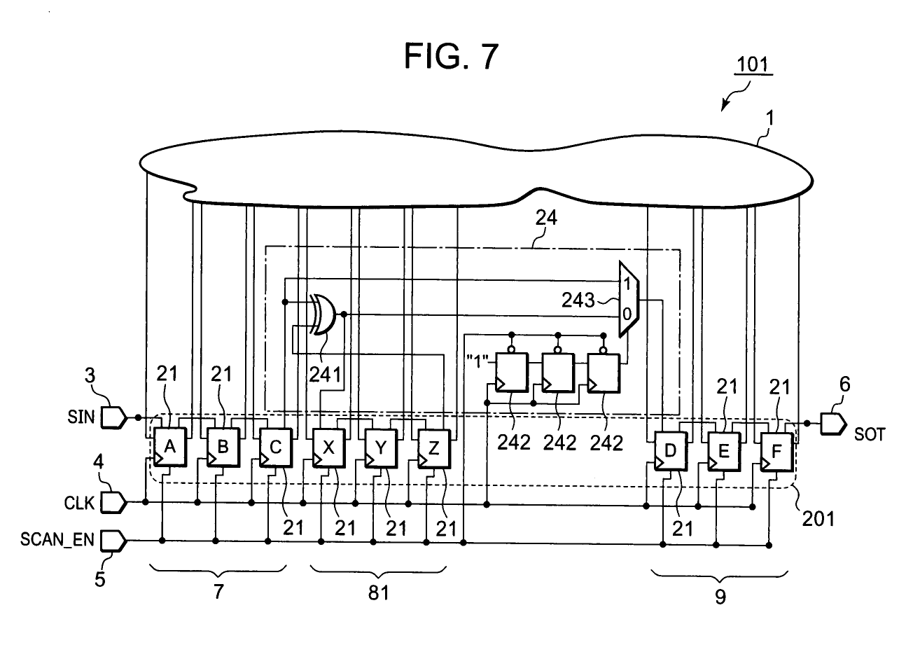

As shown in FIG. 7, in a semiconductor integrated circuit 101 and a scan path circuit 201 according to Embodiment 2 of the present invention, the configurations of a second scan FF group 81 and a skip circuit 24 are different from those of the semiconductor integrated circuit 100 and the scan path circuit 200 according to Embodiment 1. The other configurations are similar to those shown in FIG. 3, and hence like reference symbols are employed and their description is omitted.

The second scan FF group 81 includes serially connected S scan FFs 21 (S is an integer satisfying S≧1). Here, for simplicity of the description, the following description is given for an exemplary case of S=3. That is, the second scan FF group 81 includes three scan FFs _X, _Y, and _Z 21.

Further, the scan FF_X 21 of the first stage in the second scan FF group 81 is connected via the skip circuit 24 to the scan FF_C 21 of the last stage in the first scan FF group 7.

Further, the scan FF_Z 21 of the last stage in the second scan FF group 81 is connected via the skip circuit 24 to the scan FF_D 21 of the first stage in the third scan FF group 9.

Here, the number of scan FFs 21 provided in the second scan FF group 81 is not limited to that of this embodiment.

As shown in FIG. 7, the skip circuit 24 includes an XOR circuit 241 (logic circuit), three control FFs 242, a selector 243, and the like. Here, the number of control FFs 242 provided in the skip circuit 24 is not limited to that of this embodiment, and is sufficient when being equal to the number of scan FFs 21 provided in the second scan FF group 81.

The XOR circuit 241 calculates the exclusive logical sum over the output signals of the scan FF_C 21 and the scan FF_Z 21.

The three control FFs 242 are serially connected to each other.

FIG. 2C shown an example of a flip-flop used as the control FF 242. As shown in FIG. 2C, the control FF 242 includes a D terminal, a Q terminal, a CL terminal, and an RB terminal.

A fixed value “1” is to be input to the D terminal of the control FF 242 of the first stage. Further, the Q terminal of the control FF 242 of the last stage is connected to the control point of the selector 243. Further, the CL terminal is connected to the clock input terminal 4. The RB terminal is connected to the control signal input terminal 5.

Then, when a control signal “0” is input through the control signal input terminal 5, at the time of arise of the clock signal input through the clock input terminal 4, the three control FFs 242 are reset into a “0”-fixed state. Further, at the first rise of the clock signal after the control signal input through the control signal input terminal 5 has changed into “1”, the three control FFs 242 are released from the reset state. At the same time, the control FF 242 of the first stage holds the fixed value “1” input through the D terminal. Further, at the second rise of the clock signal, the control FF 242 of the first stage inputs the held signal “1” to the control FF 242 of the second stage and, at the same time, holds the signal of fixed value “1” input through the D terminal. Further, the control FF 242 of the second stage holds the signal “1” that is held in the control FF 242 of the first stage. Similarly, at the third rise of the clock signal, the control FF 242 of the last stage holds the signal “1”. Then, at the fourth rise of the clock signal, the control FF 242 of the last stage inputs the signal “1” to the control point of the selector 243.

Accordingly, during the time of three clocks after the control signal “1” is input through the control signal input terminal 5, the control FF 242 of the last stage inputs the signal “0” to the control point of the selector 243.

The selector 243 has a first input point, a second input point, a control point, and an output point.

The first input point (“1” of FIG. 7) is connected to the SO terminal of the scan FF_C 21 of the last stage in the first scan FF group 7. The second input point (“0” of FIG. 7) is connected to the XOR circuit 241. Further, the output point is connected to the SI terminal of the scan FF_D 21 of the first stage in the third scan FF group 9.

Then, on the basis of the control signal input through the control point, the selector 243 selects any one of the signal input through the first input point and the signal input through the second input point so as to input the signal to the scan FF_D 21.

Specifically, when a control signal “1” is input through the control point, the selector 243 selects the signal input through the first input point so as to input the signal to the scan FF_D 21. That is, when the control signal “1” is input, the selector 243 selects the output signal of the scan FF_C 21 so as to input the signal to the scan FF_D 21.

Further, when a control signal “0” is input through the control point, the selector 243 selects the signal input through the second input point so as to input the signal to the scan FF_D 21. That is, when the control signal “0” is input, the selector 243 selects the output signal of the XOR circuit 241 so as to input the signal to the scan FF_D 21.

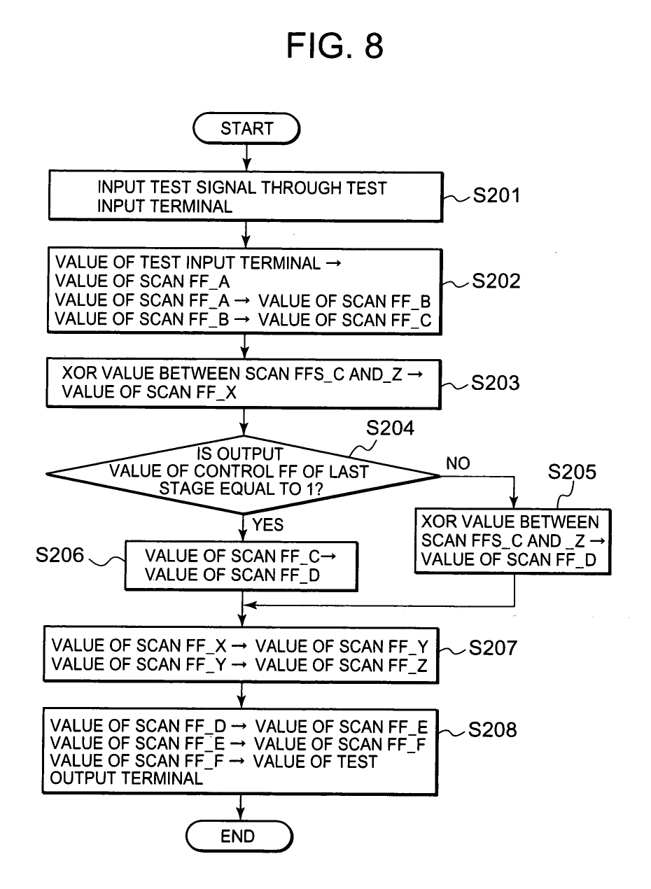

Next, the shift operation in the scan path circuit 201 according to Embodiment 2 of the present invention is described below with reference to a flow chart shown in FIG. 8. Here, the processings in Steps S201, S202, and S208 are similar to those in Steps S101, S102, and S107 shown in FIG. 5, and hence the description thereof is omitted.

In synchronization with the fourth rise of the clock signal input through the clock input terminal 4, the exclusive logical sum between the test signal at the first bit that is held in the scan FF_C 21 and the signal that is held in the scan FF_Z 21 is held in the scan FF_X 21 (Step S203).

Further, at that time, the selector 243 determines whether the signal input through the control point from the control FF 242 of the last stage is “1” (Step S204).

In Step S204, when the selector 243 determines that the signal input through the control point is “0” (Step S204; No), the selector 243 selects the signal input through the second input point so as to input the signal to the scan FF_D 21. In other words, the selector 243 selects the signal output from the XOR circuit 241 so as to input the signal to the scan FF_D 21. That is, the selector 243 inputs to the scan FF_D 21 a signal obtained as the exclusive logical sum over the output signals of the scan FF_C 21 and the scan FF_Z 21.

Further, the scan FF_D 21 holds the signal input from the selector 243 (Step S205).

In Step S204, when the selector 243 determines that the signal input through the control point is “1” (Step S204; Yes), the selector 243 selects the signal input through the first input point so as to input the signal to the scan FF_D 21. In other words, the selector 243 selects the signal output from the scan FF_C 21 so as to input the signal to the scan FF_D 21. That is, the selector 243 inputs the test signal at the first bit to the scan FF_D 21.

Further, the scan FF_D 21 holds the signal input from the selector 243 (Step S206).

Then, in synchronization with the fifth rise of the clock signal input through the clock input terminal 4, the signal that is held in the scan FF_X 21 is held in the scan FF_Y 21. Further, in synchronization with the sixth rise of the clock signal, the signal that is held in the scan FF_Y 21 is held in the scan FF_Z 21. (Step S207).

That is, in the scan path circuit 201 according to this embodiment, shift input of a signal into the nine scan FFs 21 takes the time of six clocks.

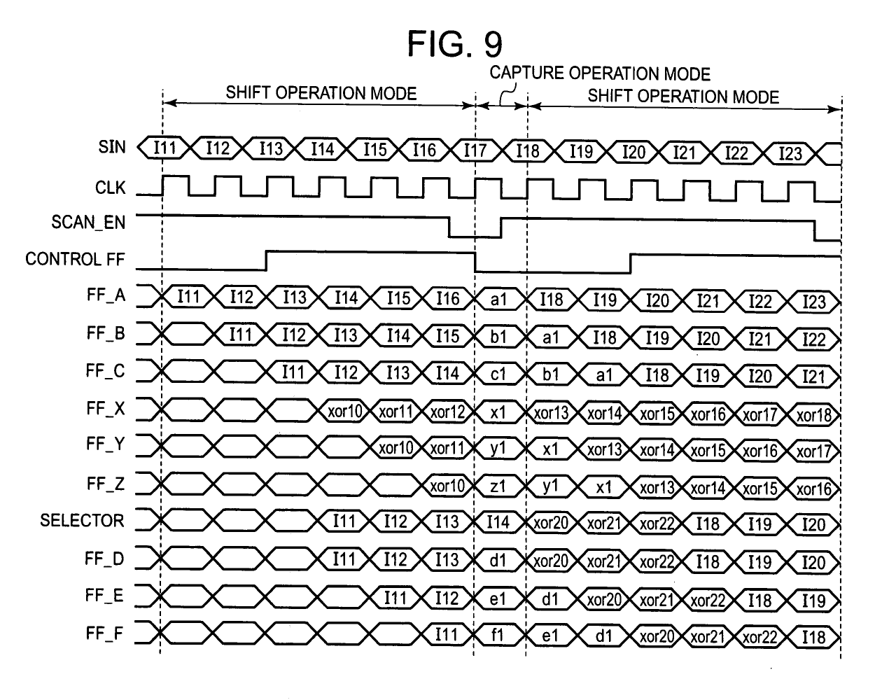

Next, changes over time in the output signals of the individual terminals, the held signals in the individual scan FFs 21, the held signal in the control FF 242 of the last stage, and the output signal of the selector 243 in the scan path circuit 201 according to Embodiment 2 of the present invention are described below with reference to a timing chart shown in FIG. 9.

Here, in an initial state, it is assumed that each scan FF 21 holds an indeterminate value and that the control FF 242 of the last stage holds “0”.

First, a control signal “1” that instructs a shift operation mode is input through the control signal input terminal 5, while a test signal “I11” is input through the test input terminal 3. Then, in synchronization with the first rise of the clock signal, the scan FF 21 is set into a shift operation mode. Accordingly, the scan FF_A 21 holds the test signal “I11”. Further, each of the scan FFs _B, _C, _Y, _Z, _E, and _F 21 holds the signal of a scan FF 21 of the preceding stage.

Further, as shown in FIG. 9, in synchronization with the first rise of the clock signal input through the clock input terminal 4, the control FF 242 of the last stage holds the held signal “0” in the control FF 242 of the preceding stage. At the same time, the control FF 242 of the last stage outputs the signal “0” to the control point of the selector 243. Thus, the selector 243 inputs to the scan FF_D 21 the signal input through the second input point. Then, the scan FF_D 21 holds the output signal of the XOR circuit 241. Further, the scan FF_X 21 holds the signal of exclusive logical sum between the output signal of the scan FF_C 21 and the output signal of the scan FF_Z 21. That is, the scan FFs _B to _F and _X to _Z hold an indeterminate value.

Similarly, in synchronization with the second rise of the clock signal, the scan FF_A 21 holds the test signal “I12” input through the test input terminal 3. At the same time, the scan FF_A 21 inputs the test signal “I11” to the scan FF_B 21. Further, the scan FF_B 21 holds the test signal “I11” input from the scan FF_A 21.

Further, in synchronization with the second rise of the clock signal, the control FF 242 of the last stage holds the held signal “0” in the control FF 242 of the preceding stage. At the same time, the control FF 242 of the last stage inputs the signal “0” to the control point of the selector 243. Thus, the selector 243 inputs to the scan FF_D 21 the signal input through the second input point. Then, the scan FF_D 21 holds the output signal of the XOR circuit 241.

The scan FF_X 21 holds the signal of exclusive logical sum between the output signal of the scan FF_C 21 and the output signal of the scan FF_Z 21. Each of the other scan FFs 21 holds the signal of a scan FF 21 of the preceding stage. That is, the scan FFs _C to _F and _X to _Z 21 hold an indeterminate value.

Then, in synchronization with the third rise of the clock signal, the scan FF_A 21 holds the test signal “I13”, the scan FF_B 21 holds the test signal “I12”, and the scan FF_C 21 holds the test signal “I11”.

Further, in synchronization with the third rise of the clock signal, the control FF 242 of the last stage holds the held signal “1” in the control FF 242 of the preceding stage. At the same time, the control FF 242 of the last stage inputs a signal “0” to the control point of the selector 243. Thus, the scan FF_D 21 holds the output signal of the XOR circuit 241.

The scan FF_X 21 holds the signal of exclusive logical sum between the output signal of the scan FF_C 21 and the output signal of the scan FF_Z 21. The other scan FFs 21 hold an indeterminate value.

Then, in synchronization with the fourth rise of the clock signal, the scan FF_A 21 holds the test signal “I14”, the scan FF_B 21 holds the test signal “I13”, and the scan FF_C 21 holds the test signal “I12”.

Further, at the same time, the scan FF_D 21 holds the output signal of the selector 243. At that time, the control FF 242 of the last stage inputs a signal “1” to the control point of the selector 243. Thus, the selector 243 selects the signal input through the first input point so as to input the signal to the scan FF_D 21. Accordingly, the scan FF_D 21 holds the test signal “I11” that is held in the scan FF_C 21.

Further, at the same time, the scan FF_X 21 holds the exclusive logical sum “xor10” between the signal “I11” that is held in the scan FF_C 21 and an indeterminate value that is held in the scan FF_Z 21.

The other scan FFs 21 hold an indeterminate value.

Similarly, in synchronization with the fifth rise of the clock signal, the scan FFs _A, _B, _C, _X, _Y, and _D 21 hold “I15”, “I14”, “I13”, “xor11”, “xor10”, and “I12”, respectively. Further, the scan FF_E 21 holds the test signal “I11” that is held in the scan FF_D 21. Further, the other scan FFs 21 hold an indeterminate value. Here, “xor11” indicates the exclusive logical sum between “I12” that is held in the scan FF_C 21 and an indeterminate value that is held in the scan FF_Z 21.

Similarly, in synchronization with the sixth rise of the clock signal, the scan FFs _A, _B, _C, _X, _Y, _Z, _D, _E, and _F 21 hold “I16”, “I15”, “I14”, “xor12”, “xor11”, “xor10”, “I13”, “I12”, and “I11”, respectively. Here, “xor11” indicates the exclusive logical sum between “I13” that is held in the scan FF_C 21 and an indeterminate value that is held in the scan FF_Z 21.

Then, at the sixth fall of the clock signal, a control signal “0” that instructs a capture operation mode is input through the control signal input terminal 5. Then, as shown in FIG. 9, in synchronization with the seventh rise of the clock signal input through the clock input terminal 4, the control FF 242 of the last stage holds the signal “0” (“0”-fixed) Further, in synchronization with the first rise of the clock signal, the scan FF 21 is set into a capture operation mode. Thus, each scan FF 21 inputs the held test signal to the target circuit 1. Further, each scan FF 21 holds a result signal output from the target circuit 1. Specifically, the scan FFs _A, _B, _C, _X, _Y, _Z, _D, _E, and _F 21 hold the result signals “a1”, “b1”, “c1”, “x1”, “y1”, “z1”, “d1”, “e1”, and “f1”, respectively.

Then, at the seventh fall of the clock signal, a control signal “1” that instructs a shift operation mode is input through the control signal input terminal 5. Then, in synchronization with the eighth rise of the clock signal, the scan FF 21 is set into a shift operation mode. Accordingly, the scan FF_A 21 holds the test signal “I18”. Each of the scan FFs _B, _C, _Y, _Z, _E, and _F 21 holds the signal of a scan FF 21 of the preceding stage. That is, the scan FFs _B, _C, _Y, _Z, _E, and _F 21 hold the result signals “a1”, “b1”, “x1”, “y1”, “d1”, and “e1”, respectively.

Further, in synchronization with the eighth rise of the clock signal input through the clock input terminal 4, the three control FFs 242 are released from the reset state. Then, the control FF 242 of the first stage holds a signal of fixed value “1”. At this time, the control FF 242 of the last stage holds “0” which is the held signal in the control FF 242 of the preceding stage. At the same time, the control FF 242 of the last stage inputs the signal “0” to the control point of the selector 243. Thus, the selector 243 selects the signal input through the second input point so as to input the signal to the scan FF_D 21. That is, the selector 243 selects the output signal of the XOR circuit 241 so as to input the signal to the scan FF_D 21. Thus, the scan FF_D 21 holds the signal of exclusive logical sum between the signals of the scan FFs _C and _Z 21. Specifically, the scan FF_D 21 holds the signal of exclusive logical sum “xor20” between “c1” and “z1”.

Further, the scan FF_X 21 holds the signal of exclusive logical sum between the output signal of the scan FF_C 21 and the output signal of the scan FF_Z 21. That is, the scan FF_X 21 holds the exclusive logical sum “xor13” between “c1” and “z1”. Further, a signal “f1” is output through the test output terminal 6.

Then, in synchronization with the ninth rise of the clock signal, the scan FF_A 21 holds the test signal “I19”, and at the same time, inputs a test signal “I18” to the scan FF_B 21. The scan FFs _B, _C, _Y, _Z, _E, and _F 21 hold the signals “I18”, “a1”, “xor13”, “x1”, “xor20”, and “d1”, respectively. Further, the scan FF_X 21 holds the exclusive logical sum “xor14” between “b1” and “y1”. Further, a signal “e1” is output through the test output terminal 6.

Further, in synchronization with the ninth rise of the clock signal, the control FF 242 of the last stage holds the signal “0” of the control FF 242 of the preceding stage. At the same time, the control FF 242 of the last stage inputs the signal “0” to the control point of the selector 243. Thus, the selector 243 selects the signal input through the second input point so as to input the signal to the scan FF_D 21. That is, the selector 243 selects the output signal of the scan FFs _C and _Z 21 so as to input the signal to the scan FF_D 21. Accordingly, the scan FF_D 21 holds the signal of exclusive logical sum “xor21” between “b1” and “y1”.

Then, in synchronization with the tenth rise of the clock signal, the scan FF_A 21 holds the test signal “I20”, and at the same time, inputs a test signal “I19” to the scan FF_B 21. Further, the scan FFs _B, _C, _Y, _Z, _E, and _F 21 hold the signals “I19”, “I18”, “xor14”, “xor13”, “xor21”, and “xor20”, respectively. Further, the scan FF_X 21 holds the exclusive logical sum “xor15” between “a1” and “x1”. Further, a signal “d1” is output through the test output terminal 6.

Further, in synchronization with the tenth rise of the clock signal, the control FF 242 of the last stage holds the signal “1” of the control FF 242 of the preceding stage. At the same time, the control FF 242 of the last stage inputs a signal “0” to the control point of the selector 243. Thus, the selector 243 selects the signal input through the second input point so as to input the signal to the scan FF_D 21. That is, the selector 243 selects the output signal of the scan FFs _C and _Z 21 so as to input the signal to the scan FF_D 21. Accordingly, the scan FF_D 21 holds the signal of exclusive logical sum “xor22” between “a1” and “x1”.

Then, in synchronization with the eleventh rise of the clock signal, the scan FF_A 21 holds the test signal “I21”, and at the same time, inputs a test signal “I20” to the scan FF_B 21. Further, the scan FFs _B, _C, _Y, _Z, _E, and _F 21 hold the signals “I20”, “I19”, “xor15”, “xor14”, “xor22”, and “xor21”, respectively. Further, the scan FF_X 21 holds the exclusive logical sum “xor16” between “I18” and “xor13”. Further, a signal “xor20” is output through the test output terminal 6.

Further, in synchronization with the eleventh rise of the clock signal, the control FF 242 of the last stage holds the signal “1” of the control FF 242 of the preceding stage. At the same time, the control FF 242 of the last stage inputs the signal “1” to the control point of the selector 243. Thus, the selector 243 selects the signal input through the first input point so as to input the signal to the scan FF_D 21. That is, the selector 243 selects the output signal of the scan FF_C 21 so as to input the signal to the scan FF_D 21. Thus, the scan FF_D 21 holds the signal “I18”.

Similarly, in synchronization with a rise of the clock signal, the scan FF_A 21 holds the test signal input through the test input terminal 3. Each of the scan FFs _B, _C, _Y, _Z, _E, and _F 21 holds the signal of a scan FF 21 of the preceding stage. Further, the scan FF_X 21 holds the signal of exclusive logical sum between the output signal of the scan FF_C 21 and the output signal of the scan FF_Z 21. Further, the scan FF_D 21 holds the output signal of the scan FF_C 21. Then, in synchronization with a rise of the clock signal, signals “xor21”, “xor22”, and “I18” are sequentially output through the test output terminal 6. Further, at the same time, the scan FFs _A, _B, _C, _X, _Y, _Z, _D, _E, and _F 21 hold the test signals “I23”, “I22”, “I21”, “xor18”, “xor17”, “xor16”, “I20”, “I19”, and “I18”, respectively. Here, “xor17” is the exclusive logical sum between “I19” and “xor14”, while “xor18” is the exclusive logical sum between “I20” and “xor15”.

That is, during the time (first time period) of three clocks after the scan FF 21 has transited from a capture operation mode to a shift operation mode, the selector 243 selects the output signal of the XOR circuit 241 so as to input the signal to the scan FF_D 21. Further, in the time (second time period) other than the above-mentioned time of three clocks in the shift operation mode, the selector 243 selects the output signal of the scan FF_C 21 so as to input the signal to the scan FF_D 21. Thus, result signals “f1”, “e1”, “d1”, “xor20”, “xor21”, and “xor22” are output through the test output terminal 6. Here, “xor20” is the exclusive logical sum between “c1” and “z1”, while “xor21” is the exclusive logical sum between “b1” and “y1”, and while “xor22” is the exclusive logical sum between “a1” and “x1”. Accordingly, a signal in which the result signals held in the scan FFs _C, _X, _Y, and _Z 21 are reflected is output through the test output terminal 6.

As described above, according to the scan path circuit 201 and the semiconductor integrated circuit 101 according to Embodiment 2 of the present invention, in addition to that an effect similar to that of Embodiment 1 is obtained, in particular, “xor20” which is the exclusive logical sum between “c1” and “z1”, “xor21” which is the exclusive logical sum between “b1” and “y1”, and “xor22” which is the exclusive logical sum between “a1” and “x1” are sequentially output through the test output terminal 6.

This permits easier design for the patterns of test signals in comparison with a case where “xor1” which is the exclusive logical sum over “c1”, “x1”, “y1”, and “z1” is compared with an expected value.

### Modification 1

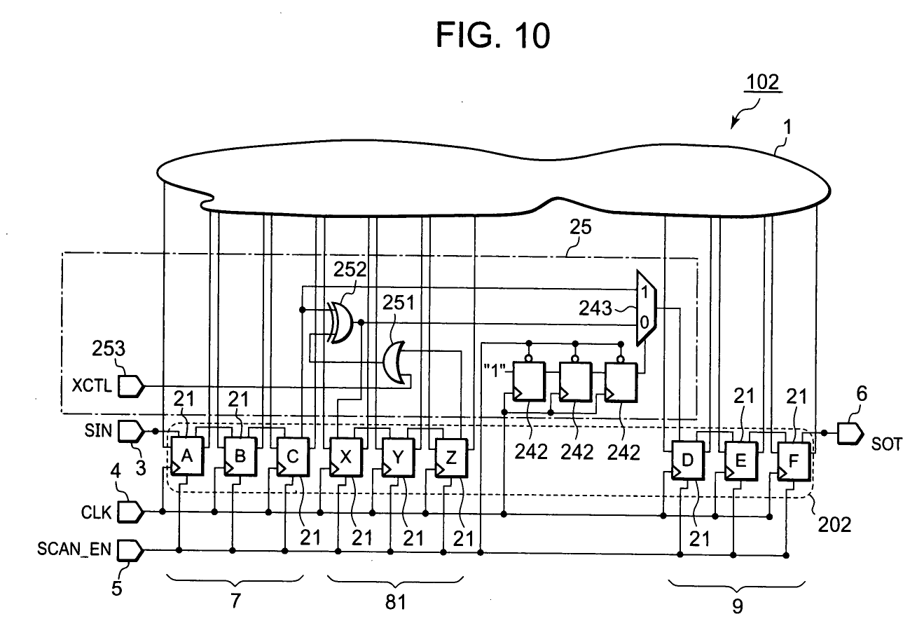

A semiconductor integrated circuit 102 and a scan path circuit 202 according to Modification 1 of Embodiment 2 of the present invention are described below with reference to FIG. 10. In the semiconductor integrated circuit 102 according to Modification 1, as shown in FIG. 10, the configuration of a skip circuit 25 is different from that of the semiconductor integrated circuit 101 and the scan path circuit 201 according to Embodiment 2. The other configurations are similar to those shown in FIG. 7, and hence like reference symbols are employed and their description is omitted.

As shown in FIG. 10, the skip circuit 25 includes an OR circuit 251, an XOR circuit 252 (logic circuit), three control FFs 242, a selector 243, a logic control terminal 253 (XCTL of FIG. 10), and the like. Here, the number of control FFs 242 provided in the skip circuit 25 is not limited to that of this modification, and is sufficient when being equal to the number of scan FFs 21 provided in the second scan FF group 81.

The OR circuit 251 is connected to the logic control terminal 253 and the SO terminal of the scan FF_Z 21. Then, the OR circuit 251 outputs to the XOR circuit 252 the logical sum between a control signal input through the logic control terminal 253 and an output signal output from the scan FF_Z 21.

The XOR circuit 252 calculates the exclusive logical sum over the output signals of the SO terminal of the scan FF_C 21 and the OR circuit 251.

Then, as shown in FIG. 9, in the time (first time period) of three clocks after the scan FF 21 has transited from a capture operation mode to a shift operation mode, in synchronization with a rise of the clock signal, the scan FF_D 21 sequentially holds signals “xor20”, “xor21”, and “xor22”. Here, for example, when a signal “1” is input through the logic control terminal 253, the signals “xor20”, “xor21”, and “xor22” do not reflect the signals “z1”, “y1”, and “x1”, respectively. That is, the signals “xor20”, “xor21”, and “xor22” have values that reflect solely “c1”, “b1”, and “a1”, respectively.

Thus, when the signal “1” is input through the logic control terminal 253, the values of “xor20”, “xor21”, and “xor22” output through the test output terminal 6 can become values that reflect solely “c1”, “b1”, and “a1”, respectively.

By virtue of this, when the signals “xor20”, “xor21”, and “xor22” output through the test output terminal 6 disagree with expected values, the result signal of which of the scan FF 21 of the first scan FF group 7 and the scan FF 21 of the second scan FF group 81 disagrees with the expected value can be determined easily. Thus, a fault in the target circuit 1 can be detected more easily.

### Embodiment 3

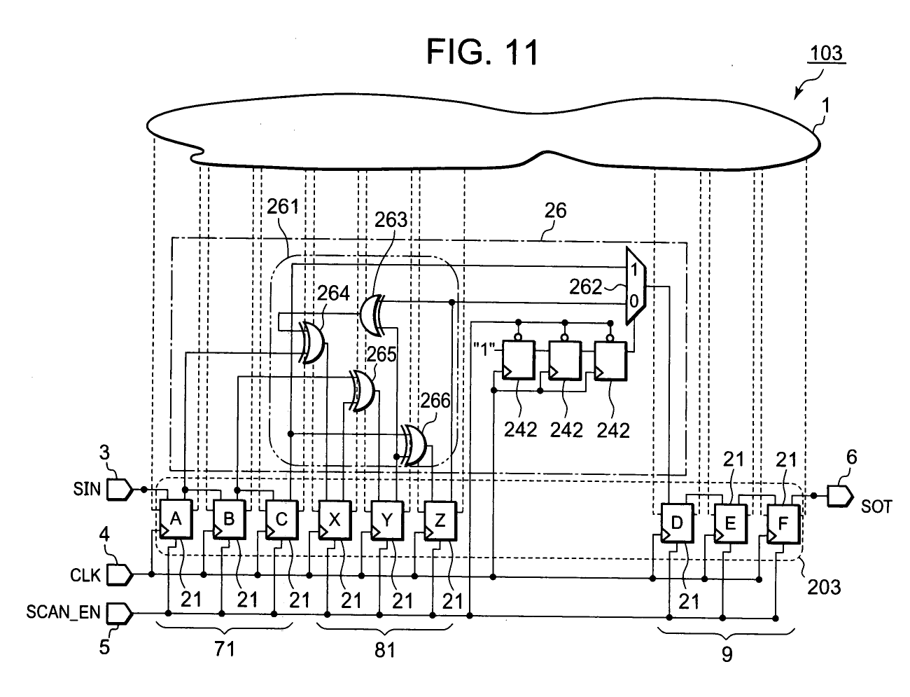

As shown in FIG. 11, in a semiconductor integrated circuit 103 and a scan path circuit 203 according to Embodiment 3 of the present invention, the configurations of a first scan FF group 71, a second scan FF group 82, and a skip circuit 26 are different from those of the semiconductor integrated circuit 101 and the scan path circuit 201 according to Embodiment 2. The other configurations are similar to those shown in FIG. 7, and hence like reference symbols are employed and their description is omitted.

The first scan FF group 71 includes serially connected K scan FFs 21 (K is an integer satisfying K≧1). Here, for simplicity of the description, the following description is given for an exemplary case of K=3. That is, the first scan FF group 71 includes three scan FFs _A, _B, and _C 21.

Further, the scan FF_A 21 of the first stage in the first scan FF group 71 is connected to the test input terminal 3.

Further, the SO terminal of the scan FF 21 of the first scan FF group 71 is connected to the SI terminal of the scan FF 21 of the subsequent stage, and is connected to the skip circuit 26.

Further, the SO terminal of the scan FF_C 21 of the last stage in the first scan FF group 71 is connected to the skip circuit 26.

Here, the number of scan FFs 21 provided in the first scan FF group 71 is not limited to that of this embodiment.

The second scan FF group 82 includes S scan FFs 21 (S is an integer satisfying S≧1). Here, for simplicity of the description, the following description is given for an exemplary case of S=3. That is, the second scan FF group 82 includes three scan FFs _X, _Y, and _Z 21.

Further, the SI terminal of the scan FF 21 in the second scan FF group 82 is connected via the skip circuit 26 to the first scan FF group 71. Further, the SO terminal of the scan FF_Z 21 of the last stage in the second scan FF group 82 is connected to a second input point (described later) of the selector 262 of the skip circuit 26, and is connected to the skip circuit 26. Further, the SO terminals of the other scan FFs 21 of the second scan FF group 82 are connected to the skip circuit 26.

Here, the number of scan FFs 21 provided in the second scan FF group 82 is not limited to that of this embodiment.

As shown in FIG. 11, the skip circuit 26 includes a multi input signature register (MISR) 261, three control FFs 242, a selector 262, and the like. Here, the number of control FFs 242 provided in the skip circuit 26 is not limited to that of this embodiment, and is sufficient when being equal to the number of scan FFs 21 provided in the second scan FF group 82.

The multi input signature register 261 includes a plurality of XOR circuits each for calculating the exclusive logical sum between the output signal of the scan FF 21 of k-th stage (k is an integer satisfying 1≦k≦K) in the first scan FF group 71 and the output signal of the scan FF 21 of s-th stage (s is an integer satisfying 1≦s≦S) in the second scan FF group 82.

Specifically, the multi input signature register 261 includes a first XOR circuit 263, a second XOR circuit 264, a third XOR circuit 265, and a fourth XOR circuit 266.

The first XOR circuit 263 calculates the exclusive logical sum between the output signal of the scan FF_Y 21 and the output signal of the scan FF_Z 21, and then inputs the result to the second XOR circuit 264.

The second XOR circuit 264 calculates the exclusive logical sum between the output signal of the scan FF_A 21 and the output signal of the first XOR circuit 263, and then inputs the result to the scan FF_X 21.

The third XOR circuit 265 calculates the exclusive logical sum between the output signal of the scan FF_B 21 and the output signal of the scan FF_X 21, and then inputs the result to the scan FF_Y 21.

The fourth XOR circuit 266 calculates the exclusive logical sum between the output signal of the scan FF_C 21 and the output signal of the scan FF_Y 21, and then inputs the result to scan FF_Z 21.

The selector 262 has a first input point, a second input point, a control point, and an output point.

The first input point (“1” of FIG. 11) is connected to the SO terminal of the scan FF_C 21 of the last stage in the first scan FF group 71. The second input point (“0” of FIG. 11) is connected to the SO terminal of the scan FF_Z 21 of the last stage in the second scan FF group 82. Further, the output point is connected to the SI terminal of the scan FF_D 21 of the first stage in the third scan FF group 9.

Then, on the basis of the control signal input through the control point, the selector 262 selects any one of the signal input through the first input point and the signal input through the second input point so as to input the signal to the scan FF_D 21.

Specifically, when a control signal “1” is input through the control point, the selector 262 selects the signal input through the first input point so as to input the signal to the scan FF_D 21. That is, when the control signal “1” is input, the selector 262 selects the output signal of the scan FF_C 21 so as to input the signal to the scan FF_D 21.

Further, when a control signal “0” is input through the control point, the selector 262 selects the signal input through the second input point so as to input the signal to the scan FF_D 21. That is, when the control signal “0” is input, the selector 262 selects the output signal of the scan FF_Z 21 so as to input the signal to the scan FF_D 21.

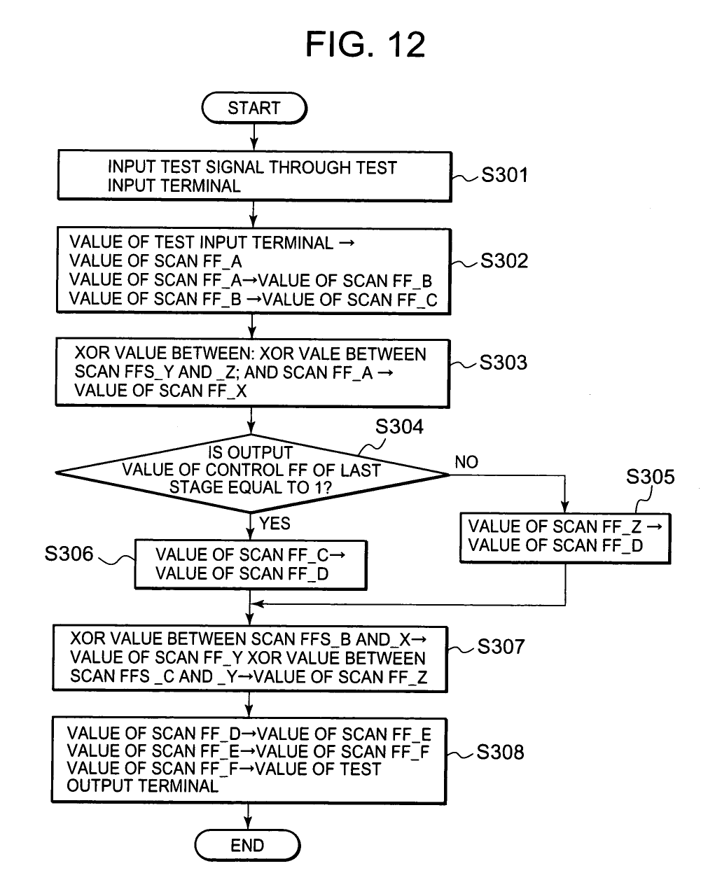

Next, the shift operation in the scan path circuit 203 according to Embodiment 3 of the present invention is described below with reference to a flow chart shown in FIG. 12. Here, the processings in Steps S301, S302, and S308 are similar to those in Steps S201, S202, and S208 shown in FIG. 8, and hence the description thereof is omitted.

In synchronization with the fourth rise of the clock signal input through the clock input terminal 4, the scan FF_X 21 holds the exclusive logical sum between: the exclusive logical sum between the scan FF_Y 21 and the scan FF_Z 21; and the test signal at the third bit that is held in the scan FF_A 21 (Step S303).

Further, at that time, the selector 262 determines whether the signal input through the control point from the control FF 242 of the last stage is “1” (Step S304).

In Step S304, when the selector 262 determines that the signal input through the control point is “0” (Step S304; No), the selector 262 selects the signal input through the second input point so as to input the signal to the scan FF_D 21. In other words, the selector 262 selects the output signal of the scan FF_Z 21 so as to input the signal to the scan FF_D 21.

Further, the scan FF_D 21 holds the signal input from the selector 262 (Step S305).

In Step S304, when the selector 262 determines that the signal input through the control point is “1” (Step S304; Yes), the selector 262 selects the signal input through the first input point so as to input the signal to the scan FF_D 21. In other words, the selector 262 selects the signal output from the scan FF_C 21 so as to input the signal to the scan FF_D 21. That is, the selector 262 inputs the test signal at the first bit to the scan FF_D 21.

Further, the scan FF_D 21 holds the signal input from the selector 262 (Step S306).

Next, in synchronization with the fifth rise of the clock signal input through the clock input terminal 4, the signal of exclusive logical sum between the output signal of the scan FF_B 21 and the output signal of the scan FF_X 21 is held in the scan FF_Y 21. Further, in synchronization with the sixth rise of the clock signal, the output signal of the scan FF_C 21 and the signal that is held in the scan FF_Y 21 are held in the scan FF_Z 21 (Step S307).

That is, in the scan path circuit 203 according to this embodiment, shift input of a signal into the nine scan FFs 21 takes the time of six clocks.

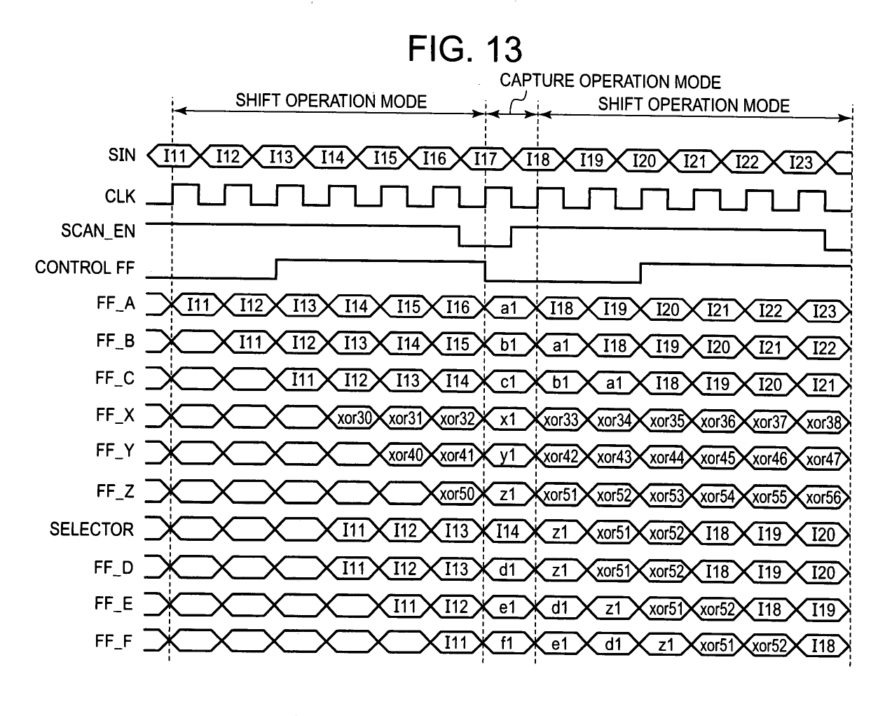

Next, changes over time in the output signals of the individual terminals, the held signals in the individual scan FFs 21, the held signal in the control FF 242 of the last stage, and the output signal of the selector 262 in the scan path circuit 203 according to Embodiment 3 of the present invention are described below with reference to a timing chart shown in FIG. 13.

Here, in an initial state, it is assumed that each scan FF 21 holds an indeterminate value and that the control FF 242 of the last stage holds “0”.

First, a control signal “1” that instructs a shift operation mode is input through the control signal input terminal 5, while a test signal “I11” is input through the test input terminal 3. Then, in synchronization with the first rise of the clock signal, the scan FF 21 is set into a shift operation mode. Accordingly, the scan FF_A 21 holds the test signal “I11”. Further, each of the scan FFs _B, _C, _E, and _F 21 holds the signal of a scan FF 21 of the preceding stage.

Further, as shown in FIG. 13, in synchronization with the first rise of the clock signal input through the clock input terminal 4, the control FF 242 of the last stage holds the held signal “1” of the control FF 242 of the preceding stage. At the same time, the control FF 242 of the last stage inputs a signal “0” to the control point of the selector 262. Accordingly, the selector 262 selects the signal input through the second input point to the scan FF_D 21. Thus, the scan FF_D 21 holds the output signal of the scan FF_Z 21.

Further, the scan FF_X 21 holds the signal of exclusive logical sum between: the exclusive logical sum between the output signal of the scan FF_Y 21 and the output signal of the scan FF_Z 21; and the output signal of the scan FF_A 21. The scan FF_Y 21 holds the signal of exclusive logical sum between the output signal of the scan FF_B 21 and the output signal of the scan FF_X 21. The scan FF_Z 21 holds the signal of exclusive logical sum between the output signal of the scan FF_C 21 and the output signal of the scan FF_Y 21. That is, the scan FFs _B to _F and _X to _Z 21 hold an indeterminate value.

Similarly, in synchronization with the second rise of the clock signal, the scan FF_A 21 holds the test signal “I12” input through the test input terminal 3. At the same time, the scan FF_A 21 inputs the test signal “I11” to the scan FF_B 21. Further, the scan FF_B 21 holds the test signal “I11” input from the scan FF_A 21.

Further, in synchronization with the second rise of the clock signal, the control FF 242 of the last stage holds the held signal “0” in the control FF 242 of the preceding stage. At the same time, the control FF 242 of the last stage inputs the signal “0” to the control point of the selector 262. Thus, the scan FF_D 21 holds the output signal of the scan FF_Z 21.

Further, the scan FF_X 21 holds the signal of exclusive logical sum between: the exclusive logical sum between the output signal of the scan FF_Y 21 and the output signal of the scan FF_Z 21; and the output signal of the scan FF_A 21. The scan FF_Y 21 holds the signal of exclusive logical sum between the output signal of the scan FF_B 21 and the output signal of the scan FF_X 21. The scan FF_Z 21 holds the signal of exclusive logical sum between the output signal of the scan FF_C 21 and the output signal of the scan FF_Y 21. Each of the other scan FFs 21 similarly holds the signal of a scan FF 21 of the preceding stage. That is, the scan FFs _C to _F and _X to _Z 21 hold an indeterminate value.

Then, in synchronization with the third rise of the clock signal, the scan FF_A 21 holds the test signal “I13”, the scan FF_B 21 holds the test signal “I12”, and the scan FF_C 21 holds the test signal “I11”.

Further, in synchronization with the third rise of the clock signal, the control FF 242 of the last stage holds the held signal “1” in the control FF 242 of the preceding stage. At the same time, the control FF 242 of the last stage inputs a signal “0” to the control point of the selector 262. Thus, the scan FF_D 21 holds the output signal of the scan FF_Z 21. The other scan FFs 21 hold an indeterminate value.

Then, in synchronization with the fourth rise of the clock signal, the scan FF_A 21 holds the test signal “I14”, the scan FF_B 21 holds the test signal “I13”, and the scan FF_C 21 holds the test signal “I12”.

Further, at the same time, the scan FF_D 21 holds the output signal of the selector 262. At that time, the control FF 242 of the last stage inputs a signal “1” to the control point of the selector 262. Thus, the selector 262 selects the signal input through the first input point so as to input the signal to the scan FF_D 21. Accordingly, the scan FF_D 21 holds the test signal “I11” that is held in the scan FF_C 21.

Further, at the same time, the scan FF_X 21 holds the exclusive logical sum “xor30” between: an indeterminate value which is the exclusive logical sum between the scan FF_Y 21 and the scan FF_Z 21; and “I13” that is held in the scan FF_A 21.

The other scan FFs 21 hold an indeterminate value.

Similarly, in synchronization with the fifth rise of the clock signal, the scan FFs _A, _B, _C, _X, and _D 21 hold “I15”, “I14”, “I13”, “xor31”, and “I12”, respectively. Further, the scan FF_E 21 holds the test signal “I11” that is held in the scan FF_D 21. Further, the scan FF_Y 21 holds the exclusive logical sum “xor40” between “I13” that is held in the scan FF_B 21 and “xor30” that is held in the scan FF_X 21. Further, the other scan FFs 21 hold an indeterminate value. Here, “xor31” held in the scan FF_X 21 is the exclusive logical sum between: an indeterminate value which is the exclusive logical sum between the scan FF_Y 21 and the scan FF_Z 21; and “I14” that is held in the scan FF_A 21.

Similarly, in synchronization with the sixth rise of the clock signal, the scan FFs _A, _B, _C, _X, _Y, _Z, _D, _E, and _F 21 hold “I16”, “I15”, “I14”, “xor32”, “xor41”, “xor50”, “I13”, “I12”, and “I11”, respectively. Here, “xor32” is the exclusive logical sum between: the exclusive logical sum between the output signal “xor40” of the scan FF_Y 21 and an indeterminate value in the scan FF_Z 21; and “I15” that is held in the scan FF_A 21. “xor41” is the exclusive logical sum between the output signal “I14” of the scan FF_B 21 and “xor31” that is held in the scan FF_X 21. “xor50” is the exclusive logical sum between the output signal “I13” of the scan FF_C 21 and “xor40” that is held in the scan FF_Y 21.

Then, at the sixth fall of the clock signal, a control signal “0” that instructs a capture operation mode is input through the control signal input terminal 5. Then, as shown in FIG. 13, in synchronization with the seventh rise of the clock signal input through the clock input terminal 4, the control FF 242 of the last stage holds the signal “0” (“0”-fixed). Further, in synchronization with the first rise of the clock signal, the scan FF 21 is set into a capture operation mode. Thus, each scan FF 21 inputs the held test signal to the target circuit 1. Further, each scan FF 21 holds a result signal output from the target circuit 1. Specifically, the scan FFs _A, _B, _C, _X, _Y, _Z, _D, _E, and _F 21 hold the result signals “a1”, “b1”, “c1”, “x1”, “y1”, “z1”, “d1”, “e1”, and “f1”, respectively.

Then, at the seventh fall of the clock signal, a control signal “1” that instructs a shift operation mode is input through the control signal input terminal 5. Then, in synchronization with the eighth rise of the clock signal, the scan FF 21 is set into a shift operation mode. Accordingly, the scan FF_A 21 holds the test signal “I18”. Each of the scan FFs _B, _C, _E, and _F 21 holds the signal of a scan FF 21 of the preceding stage. That is, the scan FFs _B, _C, _E, and _F 21 hold the result signals “a1”, “b1”, “d1”, and “e1”, respectively.

Further, in synchronization with the eighth rise of the clock signal input through the clock input terminal 4, the three control FFs 242 are released from the reset state. Then, the control FF 242 of the first stage holds a signal of fixed value “1”. At this time, the control FF 242 of the last stage holds “0” which is the held signal in the control FF 242 of the preceding stage. At the same time, the control FF 242 of the last stage inputs a signal “0” to the control point of the selector 262. Thus, the selector 262 selects the signal input through the second input point so as to input the signal to the scan FF_D 21. That is, the selector 262 selects the output signal “z1” of the scan FF_Z 21 so as to input the signal to the scan FF_D 21. Thus, the scan FF_D 21 holds the signal “z1”.

Further, the scan FF_X 21 holds the signal of exclusive logical sum “xor33” between: the exclusive logical sum between the output signal “y1” of the scan FF_Y 21 and the output signal “z1” of the scan FF_Z 21; and “a1” that is held in the scan FF_A 21. Further, the scan FF_Y 21 holds the signal of exclusive logical sum “xor42” between the output signal “b1” of the scan FF_B 21 and the output signal “x1” of the scan FF_X 21. Further, the scan FF_Z 21 holds the signal of exclusive logical sum “xor51” between the output signal “c1” of the scan FF_C 21 and the output signal “y1” of the scan F_Y 21. Further, a signal “f1” is output through the test output terminal 6.

Then, in synchronization with the ninth rise of the clock signal, the scan FF_A 21 holds the test signal “I19”, and at the same time, inputs a test signal “I18” to the scan FF_B 21. The scan FFs _B, _C, _E, and _F 21 hold the signals “I18”, “a1”, “z1”, and “d1”, respectively.

Further, in synchronization with the ninth rise of the clock signal, the control FF 242 of the last stage holds the signal “0” of the control FF 242 of the preceding stage. At the same time, the control FF 242 of the last stage inputs the signal “0” to the control point of the selector 262. Thus, the selector 262 selects the signal input through the second input point so as to input the signal to the scan FF_D 21. That is, the selector 262 selects the output signal “xor51” of the scan FF_Z 21 so as to input the signal to the scan FF_D 21. Accordingly, the scan FF_D 21 holds the signal of exclusive logical sum “xor51” between “c1” and “y1”.

Further, the scan FF_X 21 holds the signal of exclusive logical sum “xor34” between: the exclusive logical sum between the output signal “xor42” of the scan FF_Y 21 and the output signal “xor51” of the scan FF_Z 21; and “I18” that is held in the scan FF_A 21. Further, the scan FF_Y 21 holds the signal of exclusive logical sum “xor43” between the output signal “a1” of the scan FF_B 21 and the output signal “xor33” of the scan FF_X 21. Further, the scan FF_Z 21 holds the signal of exclusive logical sum “xor52” between the output signal “b1” of the scan FF_C 21 and the output signal “xor42” of the scan FF_Y 21. Further, a signal “e1” is output through the test output terminal 6.

Then, in synchronization with the tenth rise of the clock signal, the scan FF_A 21 holds the test signal “I20”, and at the same time, inputs a test signal “I19” to the scan FF_B 21. Further, the scan FFs _B, _C, _E, and _F 21 hold the signals “I19”, “I18”, “xor51”, and “z1”, respectively.

Further, in synchronization with the tenth rise of the clock signal, the control FF 242 of the last stage holds the signal “1” of the control FF 242 of the preceding stage. At the same time, the control FF 242 of the last stage inputs a signal “0” to the control point of the selector 262. Thus, the selector 262 selects the signal input through the second input point so as to input the signal to the scan FF_D 21. That is, the selector 262 selects the output signal “xor52” of the scan FF_Z 21 so as to input the signal to the scan FF_D 21. Accordingly, the scan FF_D 21 holds the signal of exclusive logical sum “xor52” between “b1” and “xor42”. Here, “xor42” is exclusive logical sum between “b1” and “x1”.

Further, the scan FF_X 21 holds the signal of exclusive logical sum “xor35” between: the exclusive logical sum between the output signal “xor43” of the scan FF_Y 21 and the output signal “xor52” of the scan FF_Z 21; and “I19” that is held in the scan FF_A 21. Further, the scan FF_Y 21 holds the signal of exclusive logical sum “xor44” between the output signal “I18” of the scan FF_B 21 and the output signal “xor34” of the scan FF_X 21. Further, the scan FF_Z 21 holds the signal of exclusive logical sum “xor53” between the output signal “a1” of the scan FF_C 21 and the output signal “xor43” of the scan FF_Y 21. Further, a signal “d1” is output through the test output terminal 6.

Then, in synchronization with the eleventh rise of the clock signal, the scan FF_A 21 holds the test signal “I21”, and at the same time, inputs a test signal “I20” to the scan FF_B 21. Further, the scan FFs _B, _C, _E, and _F 21 hold the signals “I20”, “I19”, “xor52”, and “xor51”, respectively.

Further, in synchronization with the eleventh rise of the clock signal, the control FF 242 of the last stage holds the signal “1” of the control FF 242 of the preceding stage. At the same time, the control FF 242 of the last stage inputs the signal “1” to the control point of the selector 262. Thus, the selector 262 selects the signal input through the first input point so as to input the signal to the scan FF_D 21. That is, the selector 262 selects the output signal of the scan FF_C 21 so as to input the signal to the scan FF_D 21. Thus, the scan FF_D 21 holds the signal “I18”.

Further, the scan FF_X 21 holds the signal of exclusive logical sum “xor36” between: the exclusive logical sum between the output signal “xor44” of the scan FF_Y 21 and the output signal “xor53” of the scan FF_Z 21; and “I20” that is held in the scan FF_A 21. Further, the scan FF_Y 21 holds the signal of exclusive logical sum “xor45” between the output signal “I19” of the scan FF_B 21 and the output signal “xor35” of the scan FF_X 21. Further, the scan FF_Z 21 holds the signal of exclusive logical sum “xor54” between the output signal “I18” of the scan FF_C 21 and the output signal “xor44” of the scan FF_Y 21. Further, a signal “z1” is output through the test output terminal 6.

Similarly, in synchronization with a rise of the clock signal, the scan FF_A 21 holds the test signal input through the test input terminal 3. Each of the scan FFs _B, _C, _E, and _F 21 holds the signal of a scan FF 21 of the preceding stage. Further, the scan FF_X 21 holds the signal of exclusive logical sum between: the exclusive logical sum between the output signal of the scan FF_Y 21 and the output signal of the scan FF_Z 21; and the output signal of the scan FF_A 21. The scan FF_Y 21 holds the exclusive logical sum between the output signal of the scan FF_B 21 and the output signal of the scan FF_X 21. The scan FF_Z 21 holds the exclusive logical sum between the output signal of the scan FF_C 21 and the output signal of the scan FF_Y 21. Further, the scan FF_D 21 holds the output signal of the scan FF_C 21. Then, in synchronization with a rise of the clock signal, signals “xor51”, “xor52”, and “I18” are sequentially output through the test output terminal 6. Further, at the same time, the scan FFs _A, _B, _C, _X, _Y, _Z, _D, _E, and _F 21 hold the test signals “I23”, “I22”, “I21”, “xor38”, “xor47”, “xor56”, “I20”, “I19”, and “I18”, respectively.

That is, during the time (first time period) of three clocks after the scan FF 21 has transited from a capture operation mode to a shift operation mode, the selector 262 selects the output signal of the scan FF_Z 21 so as to input the signal to the scan FF_D 21. Further, in the time (second time period) other than the above-mentioned time of three clocks in the shift operation mode, the selector 262 selects the output signal of the scan FF_C 21 so as to input the signal to the scan FF_D 21. Thus, result signals “f1”, “e1”, “d1”, “z1”, “xor51”, and “xor52” are output through the test output terminal 6. Here, “xor51” is the exclusive logical sum between “c1” and “y1”, while “xor52” is the exclusive logical sum between “b1” and “xor42”, and while “xor42” is the exclusive logical sum between “b1” and “x1”. Accordingly, a signal in which the result signals held in the scan FFs _B, _C, _X, _Y, and _Z 21 are reflected is output through the test output terminal 6.

As described above, according to the scan path circuit 203 and the semiconductor integrated circuit 103 according to Embodiment 3 of the present invention, in addition to that an effect similar to that of Embodiment 2 is obtained, in particular, a signal in which the result signals held in the scan FFs _B, _C, _X, _Y, and _Z 21 are reflected is output through the test output terminal 6.

Then, when the signal output through the test output terminal 6 is compared with an expected signal, a fault in the circuit to which each scan FF 21 is connected can be detected.

Here, a plurality of sets of the first scan FF group 7 (71), the second scan FF group 8 (81, 82), and the third scan FF group 9 may be connected to each other so that the scan path circuit 200 (201, 202, 203) is constructed. In this case, in Embodiments 1 and 2 and Modification 1, the individual sets may be connected to each other such that the third scan FF group 9 of the preceding stage serves as the first scan FF group 7 of the subsequent stage and that the first scan FF group 7 of the subsequent stage is omitted.

As described above, according to the present invention, the time necessary in a shift operation mode of the scan FFs 21 is reduced. Here, the major part of the necessary test time is the time necessary for shift. Thus, in the present invention, since the time necessary in a shift operation mode can be reduced, the necessary test time can also be reduced.

For example, in a scan chain in which 10,000 scan FFs are serially connected to each other, when 5,000 patterns of test signals are to be shift-input, the necessary test time in a shift operation mode is assumed to be 200 ns. Here, the scan chain length is expressed by the number of scan FFs provided in one scan chain. Further, the necessary test time is approximately proportional to (number of patterns of test signals)×(scan chain length).

First, the necessary test time is calculated for a case where one scan chain is divided into four like as in the conventional case. When one scan chain is divided into four, the number of patterns of test signals increases. Then, when it is assumed that, out of 5,000 patterns of test signals, 1,000 patterns which are 20% thereof increases into 1,300 patterns, the necessary test time becomes (10,000×4,000+(10,000/4)×1,300)×200 (ns)=8.65 (sec).

Next, the necessary test time is calculated for a case where the scan FFs 21 are skipped as in the present invention. Here, the fraction of the scan FFs 21 to be skipped is assumed to be 30% of the entirety. Further, an increase in number of test signals caused by the skip of the scan FFs 21 is assumed to be 10% of the entirety. Then, the necessary test time becomes (10,000×0.7)×5,500×200 (ns)=7.70 (sec). Thus, according to the present invention, the necessary test time is reduced by approximately 11% in comparison with the conventional case. In practice, since a large number of scan path circuits are built in a semiconductor integrated circuit, even a small amount of reduction in test time per scan-path circuit can achieve a large reduction effect for the necessary test time in the entire semiconductor integrated circuit.

Here, the scan path circuit 200 (201, 202, 203) including the skip circuit 22 (24, 25, 26) according to the present invention may be applied to the divided scan chains.

What is claimed is:

1. A scan path circuit, comprising:
a first scan FF group including serially connected K scan FFs (K is an integer satisfying K≧1) and connected to an input terminal;
a second scan FF group including S scan FFs (S is an integer satisfying S≧1) that receive an output signal of the first scan FF group;
a third scan FF group including serially connected N scan FFs (N is an integer satisfying N≧1) and connected to an output terminal; and
a skip circuit that inputs, in a shift operation mode of the scan FFs, the output signal of the first scan FF group to the second scan FF group as well as to the third scan FF group.

2. A scan path circuit according to claim 1, wherein the skip circuit is configured to:
connect the second scan FF group to the third scan FF group;
input, in a first time period in the shift operation mode, to the third scan FF group a signal obtained by a logic operation on the output signal of the first scan FF group and an output signal of the second scan FF group; and
input, in a second time period other than the first time period in the shift operation mode, the output signal of the first scan FF group to the third scan FF group.

3. A scan path circuit for testing a target circuit, comprising:
a first scan FF group including serially connected K scan FFs (K is an integer satisfying K≧1) and connected to an input terminal through which a test signal is input;
a second scan FF group including S scan FFs (S is an integer satisfying S≧1) that receive an output signal of the first scan FF group;
a third scan FF group including serially connected N scan FFs (N is an integer satisfying N≧1) and connected to an output terminal through which an output signal is output; and
a skip circuit that inputs, in a shift operation mode of the scan FFs, the output signal of the first scan FF group to the second scan FF group as well as to the third scan FF group, wherein:
in a normal operation mode, the scan FFs input the test signal to the target circuit and hold a result signal output from the target circuit; and
the skip circuit inputs, in a first time period after transition from the normal operation mode to the shift operation mode, to the third scan FF group a signal obtained by a logic operation on the output signal of the first scan FF group and an output signal of the second scan FF group, and inputs, in a second time period other than the first time period in the shift operation mode, the output signal of the first scan FF group to the third scan FF group.

4. A scan path circuit according to claim 3, wherein the skip circuit comprises:
a logic circuit that performs a logic operation on an output signal of the scan FF of a last stage in the first scan FF group and output signals of the S scan FFs of the second scan FF group; and
a selector that is connected to the scan FF of the last stage in the first scan FF group and to the logic circuit and that inputs, in the first time period, an output signal of the logic circuit to the third scan FF group, and inputs, in the second time period, the output signal of the scan FF of the last stage to the third scan FF group.

5. A scan path circuit according to claim 3, wherein the skip circuit comprises:
a logic circuit that performs a logic operation on an output signal of the scan FF of a last stage in the first scan FF group and an output signal of the scan FF of the last stage in the second scan FF group; and
a selector that is connected to the scan FF of the last stage in the first scan FF group and to the logic circuit and that inputs, in the first time period, an output signal of the logic circuit to the third scan FF group, and inputs, in the second time period, the output signal of the scan FF of the last stage in the first scan FF to the third scan FF group.

6. A scan path circuit according to claim 3, wherein the skip circuit comprises:
a multi input signature register that includes a plurality of logic circuits for performing a logic operation on an output signal of the scan FF of a k-th stage (k is an integer satisfying 1≦k≦) in the first scan FF group and an output signal of the scan FF of an s-th stage (s is an integer satisfying 1≦s≦S) in the second scan FF group; and
a selector that is connected to the scan FF of a last stage in the first scan FF group and to the scan FF of the last stage in the second scan FF group, and that inputs, in the first time period, an output signal of the scan FF of the last stage in the second scan FF group to the third scan FF group, and inputs, in the second time period, an output signal of the scan FF of the last stage in the first scan FF group to the third scan FF group,
wherein an output signal of the multi input signature register is input to the second scan FF group.

7. A scan path circuit, comprising:
a first scan chain including serially connected K scan FFs (K is an integer satisfying K≧1);
a second scan chain including serially connected N scan FFs (N is an integer satisfying N≧1);
a logic circuit, wherein said scan path circuit selects one of a first path comprised of said first and said second scan chains being connected in series and a second path comprised of said first and said second scan chains being connected through said logic circuit.

8. A semiconductor integrated circuit comprising the scan path circuit according to claim 1.
